(19) United States
(12) Patent Application Publication
(10) Pub. No.: US 2026/0215269 A1
(43) Pub. Date: Jul. 23, 2026

(54) FABRICATION METHODS FOR LIQUID COOLING CHANNEL CHIP

(71) Applicant: Adeia Semiconductor Bonding Technologies Inc., San Jose, CA (US)

(72) Inventors: Gaius Gillman Fountain, JR., Youngsville, NC (US); Belgacem Haba, Saratoga, CA (US); George Carlton Hudson, Wendell, NC (US); Pawel Mrozek, San Jose, CA (US)

(21) Appl. No.: 19/423,755

(22) Filed: Dec. 17, 2025

Related U.S. Application Data
(62) Division of application No. 18/788,853, filed on Jul. 30, 2024.
(60) Provisional application No. 63/550,799, filed on Feb. 7, 2024.
(60) Provisional application No. 63/575,083, filed on Apr. 5, 2024.

(51) Int. Cl. H10W 40/47; H10W 40/40; H10W 40/43

(52) U.S. Cl. CPC H10W 40/47; H10W 40/40; H10W 40/43

(57) ABSTRACT

Methods are described related to a cold plate having protruding features for integrated cooling assemblies. The method includes patterning a first side of a substrate to form first opening patterns, patterning a second side of the substrate opposite the first side to form second opening patterns aligned with the first opening patterns and protrusion patterns. A cold plate is formed by concurrently anisotropic wet etching both sides of the substrate to form openings extending from the first side to the second side and protrusions on the second side.

### CROSS-REFERENCE TO RELATED APPLICATIONS

This application is a continuation of U.S. patent application Ser. No. 18/788,853, filed Jul. 30, 2024, which claims priority to U.S. Provisional Patent Application No. 63/550,799, filed Feb. 7, 2024, and U.S. Provisional Patent Application No. 63/575,083, filed Apr. 5, 2024, the disclosures of each application are hereby incorporated by reference herein in their entireties.

### FIELD

The present disclosure relates to advanced packaging for microelectronic devices, and in particular, cooling systems for device packages and methods of manufacturing the same.

### BACKGROUND

Energy consumption poses a critical challenge for the future of large-scale computing as the world's computing energy requirements are rising at a rate that most would consider unsustainable. Some models predict that the information, communication, and technology (ICT) ecosystem could exceed 20% of global electricity use by 2030, with direct electrical consumption by large-scale computing centers accounting for more than one-third of that energy usage. A significant portion of the energy used by such large-scale computing center centers is devoted to cooling, since even small increases in operating temperatures can negatively impact the performance of microprocessors, memory devices, and other electronic components. While some of this energy is expended to operate the cooling systems that are directly cooling the chips (e.g., heat spreaders, heat pipes, etc.), energy consumption/costs for indirect cooling can also be quite staggering. Indirect cooling energy costs include, for example, cooling or air conditioning of data center buildings. Data center buildings can house thousands, to tens of thousands or more, of high-performance chips in server racks, and each of those high-performance chips is a heat source. An uncontrolled ambient temperature in a data center will adversely affect the performance of the individual chips, and the data center system performance as a whole.

Thermal dissipation in high-power density chips (semiconductor devices/die) is also a critical challenge as improvements in chip performance, e.g., through increased gate or transistor density due to advanced processing nodes, evolution of multi-core microprocessors, etc., have resulted in increased power density and a corresponding increase in thermal flux that contributes to elevated chip temperatures. Higher density of transistors also increases the length of metal wiring on the chips, which generates its own additional thermal flux due to Joule heating of these wires due to higher currents. These elevated temperatures are undesirable as they can degrade the chip's operating performance, efficiency, reliability, and amount of remaining life. Cooling systems used to maintain the chip at a desired operating temperature typically remove heat using one or more heat dissipation devices, e.g., thermal spreaders, heat pipes, cold plates, liquid cooled heat pipe systems, thermal-electric coolers, heat sinks, etc. One or more thermal interface material(s), such as, for example, thermal paste, thermal adhesive, or thermal gap filler, may be used to facilitate heat transfer between the surfaces of a chip and heat dissipation device(s). A thermal interface material(s) (TIM(s)) is any material that is inserted between two components to enhance the thermal coupling therebetween. Unfortunately, the combined thermal resistance of (i) the thermal resistance of interfacial boundary regions between a TIM(s) and the chip and/or the heat dissipation device(s), and (ii) the thermal resistance of a thermal interface material(s) itself can inhibit heat transfer from the chip to the heat dissipation devices, undesirably reducing the cooling efficiency of the cooling system.

Generally speaking, there are multiple components between the heat dissipating sources (i.e., active circuitry) in the chips and the heat dissipation devices, each of which contributes to the system thermal resistance cumulatively along the heat transfer paths and raises chip junction temperatures from the ambient.

Such cooling systems can suffer from reduced cooling efficiency due to the design and manufacture of system components.

Accordingly, there exists a need in the art for improved energy-efficient cooling systems, by reducing system thermal resistance, and methods of manufacturing the same.

### SUMMARY

Embodiments herein provide methods of manufacturing integrated device cooling assemblies embedded in advanced device packages. Advantageously, the integrated device cooling assemblies are manufactured using a double-sided anisotropic wet etching to reduce manufacturing cost and improve manufacturing efficiency of integrated cooling assemblies.

One general aspect includes a method of manufacturing a cold plate. The method includes patterning a first side of a substrate to form first opening patterns. The method further includes patterning a second side of the substrate opposite the first side to form second opening patterns aligned with the first opening patterns and protrusion patterns. The method further comprises forming a cold plate by concurrently anisotropic wet etching both sides of the substrate to form openings extending from the first side to the second side and protrusions on the second side.

Implementations of the method for manufacturing the cold plate may include one or more of the following features. The patterns may comprise a thermal oxide layer. In one embodiment, patterning the sides of the substrate may comprise depositing a first hardmask with the first opening patterns on the first side of the substrate and depositing a second hardmask with the second opening patterns and the protrusion patterns on the second side of the substrate. The substrate may comprise crystalline silicon, and the first and second hardmasks may comprise amorphous dielectric. The amorphous dielectric may be a thermal oxide. In one embodiment, forming the cold plate through concurrent anisotropic wet etching comprises anisotropic wet etching the first side through first substrate portions exposed by the first opening patterns, anisotropic wet etching the second side through second substrate portions exposed by the second opening patterns and the protrusion patterns, and removing the first and second hardmasks. The second side of the cold plate may comprise a base surface. The base surface may be spaced apart from the semiconductor device to define a coolant chamber volume therebetween. The substrate may be a first substrate. In one embodiment, the method may further include attaching the second side of the cold plate, or a portion thereof, to a second substrate comprising a semiconductor device, the base surface being spaced apart from the semiconductor device to define a coolant chamber volume therebetween, wherein the attached cold plate and second substrate form an integrated cooling assembly. Attaching the second side of the cold plate to the second substrate may comprise direct dielectric bonding. Attaching the second side of the cold plate to the second substrate may comprise direct hybrid bonding. The method may further include activating the second side of the cold plate for bonding and directly bonding the second side of the cold plate to a second substrate comprising a semiconductor device, wherein the bonded first and second substrates form an integrated cooling assembly. Directly bonding the second side of the cold plate to the second substrate may comprise direct dielectric bonding. Directly bonding the second side of the cold plate to the second substrate may comprise direct hybrid bonding. In one embodiment, the method may further include sealingly attaching a package cover to a first side of the cold plate by use of a material layer disposed therebetween, wherein the package cover comprises an inlet opening and an outlet opening, and forming openings in the material layer to fluidly connect the inlet opening and outlet opening to the coolant chamber volume. The second side of the cold plate may not be polished prior to bonding.

One general aspect includes a device package comprising an integrated cooling assembly. The integrated cooling assembly comprises a semiconductor device and/or a cold plate bonded to the device. The cold plate comprises a first side, a second side opposite the first side, and outer sidewalls extending downwardly from the first side to a backside of the semiconductor device. The cold plate further comprises inner sidewalls extending between the first side and second side, wherein the outer sidewalls and the inner sidewalls define openings. The cold plate further comprises protrusions extending downwardly from the second side towards the backside of the semiconductor device. Lower surfaces of the protrusions are bonded to the backside of the semiconductor device. The second side, the outer sidewalls, and the backside of the semiconductor device collectively define a coolant chamber volume therebetween. Each of the inner sidewalls and the outer sidewalls includes a plurality of segments having a plurality of different textures, respectively.

Implementations of the device package may include one or more of the following features. Sidewalls of the protrusions may slope away from the second side at an angle greater than 90 degrees (°). One or more segments of the plurality of segments of at least one of the inner sidewalls and the outer sidewalls may slope towards the second side at an angle less than 90°. One or more segments of the plurality of segments of at least one of the inner sidewalls and the outer sidewalls may slope towards the second side at an angle less than 90°. One or more first segments of the inner sidewalls may slope away from the second side at an angle less than 90°, and one or more second segments of the inner sidewalls may slope away from the first side at an angle less than 90°. The protrusions may extend laterally along the second side between the openings. Each protrusion may comprise distal segments and a central segment extending between the distal segments, and a width of the distal segments between protrusion sidewalls of the protrusion is less than a width of the central segment between the protrusion sidewalls. The openings of the cold plate may comprise an inlet opening and an outlet opening. The coolant chamber volume may be in fluid communication with the inlet opening and the outlet opening. The device package may further include a package cover, the package cover having an inlet opening and an outlet opening disposed therethrough, wherein the coolant chamber volume is in fluid communication with the inlet opening and the outlet opening of the package cover. The protrusions may extend to and be bonded to the backside of the semiconductor device. The protrusions, the outer sidewalls, and the inner sidewalls may be formed through a double-sided wet etch process to concurrently wet etch the first side and the second side. The cold plate may be bonded to the backside of the semiconductor device by direct dielectric bonds. The cold plate may be bonded to the backside of the semiconductor device by direct hybrid bonds. The lower surfaces of the protrusions may be bonded to the backside of the semiconductor device by direct dielectric bonds.

### BRIEF DESCRIPTION OF THE DRAWINGS

The above and other objects and advantages of the disclosure will be apparent upon consideration of the following detailed description, taken in conjunction with the accompanying drawings, in which:

FIG. 1 illustrates a device package with an external heat sink;

FIG. 2A is a schematic plan view of an example of a system panel, in accordance with embodiments of the present disclosure;

FIG. 2B is a schematic partial sectional side view of a device package mounted on a PCB, in accordance with embodiments of the present disclosure;

FIG. 2C is a schematic exploded isometric view of the device package in FIG. 2B;

FIG. 3 is a schematic sectional view of an example device package, in accordance with embodiments of the present disclosure, that may be used with the system panel;

FIG. 4 is a schematic sectional view of an integrated cooling assembly of the device package, in accordance with embodiments of the present disclosure;

FIG. 5 is a schematic sectional view of another example device package, in accordance with embodiments of the present disclosure, that may be used with the system panel; and

FIG. 6 shows a method that can be used to manufacture the device package described herein.

FIG. 7 is a schematic sectional side view of an example device package comprising an integrated cooling assembly having a cold plate with protruding features, in accordance with some embodiments of the present disclosure, that may be used with the system panel;

FIG. 8 show a schematic sectional side view corresponding to a cold plate having protruding features, in accordance with some embodiments of the present disclosure;

FIG. 9 is a flowchart illustrating an example process for forming a cold plate through double-sided anisotropic etching, in accordance with some embodiments of the present disclosure;

FIG. 10 shows schematic frontside and backside views of example structures during formation of a cold plate through double-sided anisotropic etching, in accordance with some embodiments of the present disclosure;

FIG. 11 shows some example intermediate structures during formation of a cold plate through double-sided anisotropic etching, in accordance with some embodiments of the present disclosure; and

FIG. 12 is a flowchart illustrating an example process for assembling an integrated cooling assembly having a cold plate with protruding features, in accordance with some embodiments of the present disclosure.

The figures herein depict various embodiments of the present disclosure for purposes of illustration only. It will be appreciated that additional or alternative structures, assemblies, systems, and methods may be implemented within the principles set out by the present disclosure.

### DETAILED DESCRIPTION

As used herein, the term “substrate” means and includes any workpiece, wafer, or article that provides a base material or supporting surface from which or upon which components, elements, devices, assemblies, modules, systems, or features of the heat-generating devices, packaging components, and cooling assembly components described herein may be formed or mounted. The term substrate also includes “semiconductor substrates” that provide a supporting material upon which elements of a semiconductor device are fabricated or attached, and any material layers, features, and/or electronic devices formed thereon, therein, or therethrough. Examples of substrate material that may be used in applications that generate high thermal density include, but are not limited to, Si, GaN, SiC, InP, GaP, InGaN, AlGaInP, AlGaAs, etc.

As described below, the semiconductor substrates herein generally have a “device side,” e.g., the side on which semiconductor device elements are fabricated, such as transistors, resistors, and capacitors, and a “backside” that is opposite the device side. The term “active side” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that forms the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active sides” and “non-active sides” are also used to describe surfaces of material layers or features formed on, in, or through the semiconductor substrate, whether or not the material layers or features are ultimately present in the fabricated or assembled device. For example, in some instances, the term “active side” is used to indicate a surface of a substrate that will in the future, but does not yet, include semiconductor device elements.

Spatially relative terms are used herein to describe the relationships between elements, such as the relationships between substrates, heat-generating devices, cooling assembly components, device packaging components, and other features described below. Unless the relationship is otherwise defined, terms such as “above,” “over,” “upper,” “upwardly,” “outwardly,” “on,” “below,” “under,” “beneath,” “lower,” “top,” “bottom,” and the like are generally made with reference to the X, Y, and Z directions set forth by X, Y and Z axes in the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” and the like, either alone or in combination with a spatially relevant term include both relationships with intervening elements and direct relationships where there are no intervening elements. Furthermore, the term “horizontal” is generally made with reference to the X-axis direction and the Y-axis direction set forth in the drawings. The term “vertical” is generally made with reference to the Z-axis direction set forth in the drawings.

Various embodiments disclosed herein include bonded structures in which two or more elements are directly bonded to one another without an intervening adhesive (referred to herein as “direct bonding,” “direct dielectric bonding,” or “directly bonded”). The resultant bonds formed by this technique may be described as “direct bonds” and/or “direct dielectric bonds”. In some embodiments, direct bonding includes the bonding of a single material on the first of the two or more elements and a single material on a second one of the two or more elements, where the single material on the different elements may or may not be the same. For example, bonding a layer of one inorganic dielectric (e.g., silicon oxide) to another layer of the same or different inorganic dielectric. As discussed in more detail below, the process of direct bonding (e.g., direct dielectric bonding) provides a reduction of thermal resistance between a semiconductor device and a cold plate. Examples of dielectric materials used in direct bonding include oxides, nitrides, oxynitrides, carbonitrides, and oxycarbonitrides, etc., such as, for example, silicon oxide, silicon nitride, silicon oxynitride, silicon carbonitride, silicon oxycarbonitride, etc. Direct bonding can also include bonding of multiple materials on one element to multiple materials on the other element (e.g., hybrid bonding). As used herein, the term “hybrid bonding” refers to a species of direct bonding having both i) at least one (first) nonconductive feature directly bonded to another (second) nonconductive feature, and ii) at least one (first) conductive feature directly bonded to another (second) conductive feature, without any intervening adhesive. The resultant bonds formed by this technique may be described as “hybrid bonds” and/or “direct hybrid bonds.” In some hybrid bonding embodiments, there are many first conductive features, each directly bonded to a second conductive feature, without any intervening adhesive. In some embodiments, nonconductive features on the first element are directly bond to nonconductive features of the second element at room temperature without any intervening adhesive, which is followed by bonding of conductive features of the first element directly bonded to conductive features of the second element via annealing at slightly higher temperatures (e.g., >100° C., >200° C., >250° C., >300° C., etc.).

Unless otherwise noted, the terms “cooling assembly” and “integrated cooling assembly” generally refer to a semiconductor device and a cold plate attached to the semiconductor device. Typically, the cold plate is formed with recessed surfaces that define one or more fluid cavities (e.g., coolant chamber volume(s) or coolant channel(s)) between the cold plate and the semiconductor device. In embodiments where the cold plate is formed with plural fluid cavities, each fluid cavity may be defined by cavity dividers and/or sidewalls of the cold plate. For example, cavity dividers may be spaced apart from each other and extend laterally between opposing cold plate sidewalls (e.g., in one direction between a first pair of opposing cold plate sidewalls, or in two directions between orthogonal pairs of opposing cold plate sidewalls). The cavity dividers and the cold plate sidewalls may collectively define adjacent fluid cavities therebetween. The cold plate may comprise a polymer material.

The cold plate may be attached to the semiconductor device by use of a compliant adhesive layer or by direct bonding or hybrid bonding. Direct bonding may include direct dielectric bonding techniques as described herein and may give rise to direct dielectric bonds. Hybrid bonding may include hybrid bonding techniques as described herein and may give rise to direct hybrid bonds. For example, the cold plate may include material layers and or metal features that facilitate direct bonding or hybrid bonding with the semiconductor device. Beneficially, the backside of the semiconductor device is directly exposed to coolant fluids flowing through the integrated cooling assembly, thus providing for direct heat transfer therebetween. Unless otherwise noted, the integrated cooling assemblies described herein may be used with any desired fluid, e.g., liquid, gas, and/or vapor-phase coolants, such as water, glycol, etc.

Exemplary cooling fluids available for use in the various embodiments include: water (either purified or deionized), a glycol (e.g., ethylene glycol, propylene glycol), glycols mixed with water (e.g., ethylene glycol mixed with water (EGW) or propylene glycol mixed with water (PGW)), dielectric fluids (e.g. fluorocarbons, polyalphaolefin (PAO), isoparaffins, synthetic esters, or very high viscosity index (VHVI) oils), or mineral oils. Depending upon design and operating conditions, these fluids may be used in single-phase liquid, single-phase vapor, two-phase liquid/vapor, or two-phase solid/liquid. Additionally, multiple combinations of the aforementioned cooling fluid phases may be employed in various hybrid configurations to meet the particular cooling needs of a respective implementation and still be within the scope of the contemplated embodiments.

Additionally, in some embodiments part or all the cooling is provided by gases. Exemplary gases include atmospheric air and/or one or more inert gases such as nitrogen. Atmospheric air may be taken to mean the mixture of different gases in Earth's atmosphere made up of about 78% nitrogen and 21% oxygen.

Depending on the design needs of a fluid cooling system using the disclosed embodiments, engineered dielectric cooling fluids may be used. Some examples of dielectric fluids used for cooling semiconductors include: 3M™ Fluorinert™ Liquid FC-40—A non-flammable, dielectric fluid that can be used in direct contact with live electronics; 3M™ Novec™ Engineered Fluids—A non-flammable, dielectric fluid that can be used in direct contact with live electronics; Galden® PFPE (perfluoropolyether) products used as heat transfer fluids; EnSolv Fluoro HTF—A solvent with a high boiling point and low pour point that can be used for semiconductor wafer cooling. It is understood that in the selection of the cooling fluid, system design aspects such as operating temperatures and pressures, fluid flow rates, fluid viscosity, and other properties will require evaluation when selecting the appropriate cooling fluid.

In some embodiments, the cooling fluids may contain microparticles and/or nanoparticle additives to enhance the conductivity of the cooling fluid within the integrated cooling assemblies. Choi and Eastman (1995) from Argonne National Laboratory, U.S.A. (Yu et al., 2007) coined the word “nanofluid”. The nanofluid is an engineered fluid prepared by suspending the nano-sized (1-100 nm) particles of metals/non-metals and their oxide(s) with a base/conventional fluid. The suspension of high thermal conductivity metals/non-metals and their oxides nanoparticles enhances the thermal conductivity and heat transfer ability, etc. of the base fluid. The additives to the underlying cooling fluid may comprise for example, nanoparticles of carbon nanotube, nanoparticles of graphene, or nanoparticles of metal oxides. When the cooling fluid contains microparticles, the microparticles are typically 10 microns or in in diameter. Silicon oxide microparticles may be used.

The concentration of these micro or nanoparticles may be less than 1%, less than 0.2%, or less than 0.05%. Depending upon the liquid and micro/nanoparticle type chosen for the nanofluid, higher concentrations of 10% or less, 5% or less, or 2% or less may be used. The cooling fluids may also contain small amounts of glycol or glycols (e.g., propylene glycol, ethylene glycol etc.) to reduce frictional shear stress and drag coefficient in the cooling fluid within the integrated cooling assembly. The availability of different base fluids (e.g., water, ethylene glycol, mineral or other stable oils, etc.) and different nanomaterials provide a variety of nanomaterial options for nanofluid solutions to be used in the various embodiments. These nanomaterial option groups such as aforementioned metals (e.g., Cu, Ag, Fe, Au . . . etc.), metal oxides (e.g., TiO₂, Al₂O₃, CuO . . . etc.), carbons (e.g., carbon nanotubes (CNTs), graphene, diamond, graphite . . . etc.), or a mixture of different types of nanomaterials. Metal nanoparticles (Cu, Ag, Au . . . ) , metal oxide nanoparticles (Al₂O₃, TiO₂, CuO), and carbon-based nanoparticles are commonly employed elements. Silicon oxide nanoparticles may also be used. Using nanofluids when practicing the various embodiments disclosed herein can result in increased heat removal efficiencies and effectiveness.

The fluid control design aspects of specific embodiments may require the nanofluids to be magnetic to facilitate either movement or cessation of movement of the fluids within the semiconductor structures. Magnetic nanofluids (MNFs) are suspensions of a non-magnetic base fluid and magnetic nanoparticles. The magnetic nanoparticles may be coated with surfactant layers such as oleic acid to reduce particle agglomeration and/or settling. Magnetic nanoparticles used in MNFs are usually made of metal materials (ferromagnetic materials) such as iron, nickel, cobalt, as well as their oxides such as spinel-type ferrites, magnetite (Fe3O4), and so forth. The magnetic nanoparticles used in MNFs typically range in size from about 1 to 100 nanometers (nm).

This disclosure describes embodiments involving the architecture of system and component elements that can be employed to provide for the cooling of semi-conductor components, packaging, and boards. However, those skilled in the art will appreciate the disclosed components and arrangements can be deployed and used in scenarios where component heat up or thermal warm up is desired for a component that is currently outside the low end of the desired operational range. Components that are outside the low end of their operational range can, if started in a cold environment, experience thermal warping or cracking up to and including thermal overexpansion and contact separation that may impair the successful operation of the system. Therefore, in these scenarios, the architectures and embodiments disclosed herein can be used where the indirect thermal solutions supporting them are repurposed or operated in a hybrid configuration to provide warming fluids or heat transfer media to accomplish the warm-up or heat-up scenario. These scenarios are controlled by systems not shown here to bring temperatures up at a speed or timing that enables the materials to avoid the excessive thermal expansion or unequal thermal expansion that may occur among the materials of the semiconductor or packaging being serviced by the thermal solution. Once the component or packaging is brought up into the normal operating range, it can be safely started and brought to a useful operational state.

Considering the warm-up or heat-up embodiments introduced above, the balance of this disclosure and terms used should be viewed in a light that also considers the design option for such warm-up or heat-up. Thus, where terms such as cooling channel, cooling chamber volume, and cooling port are used, for example, such terms could also be considered as a thermal control channel, a thermal control volume, or a thermal control port, respectively. A person of skill would understand that heat flux or heat transfer would go in a different direction, but the design concepts are similar and can be successfully employed in the various embodiments.

In some embodiments, a cooling channel is a liquid cooling channel, and a liquid may flow through the liquid cooling channel. In some embodiments, the liquid may comprise a water and/or glycol (e.g., propylene glycol, ethylene glycol, and mixtures thereof).

As described below, coolant fluid flowing through a cold plate may be used to control the temperature of semiconductor devices. The fluid flowing across the surface of the semiconductor device absorbs heat and conducts heat away from the semiconductor device.

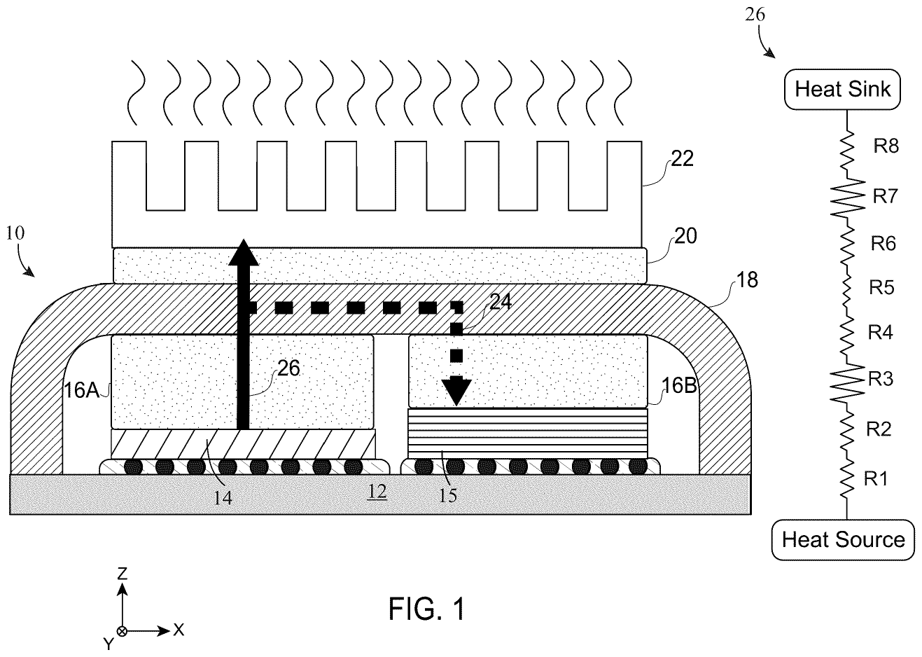

FIG. 1 is a schematic side view of a device package 10 and a heat sink 22 attached to the device package 10. The device package 10 typically includes a package substrate 12, a first device 14, a device stack 15, a heat spreader 18, and first TIM layers 16A, 16B thermally coupling the first device 14 and the device stack 15 to the heat spreader 18. The device package 10 is thermally coupled to the heat sink 22 through a second TIM layer 20. The TIM layers 16A, 16B, 20 facilitate thermal contact between components in the device package 10 and between the device package 10 and the heat sink 22.

As heat flux density increases with increasing power density in advanced semiconductor devices, the cumulative thermal resistance of the system illustrated in FIG. 1 is increasingly problematic as heat cannot be dissipated quickly enough to allow semiconductor devices to run at optimal power. Consequently, the energy efficiency of semiconductor devices is reduced. Furthermore, heat is transferred between semiconductor devices within the device package 10, as shown with heat transfer path 24 (illustrated as a dashed line), where heat may be undesirably transferred from the first device 14 having a high heat flux, such as a central processing unit (CPU) or a graphical processing unit (GPU), to the device stack 15 having low heat flux, such as memory, through the heat spreader 18.

For example, as shown in FIG. 1, each device package component and the respective interfacial boundaries therebetween have a corresponding thermal resistance that forms heat transfer path 26 (illustrated by arrow 26 in FIG. 1). The right-hand side of FIG. 1 illustrates the heat transfer path 26 as a series of thermal resistances R1-R8 between a heat source and a heat sink. Here, R1 is the thermal resistance of the bulk semiconductor material of the first device 14. R3 and R7 are the thermal resistances of the first TIM layers 16A, 16B and the second TIM layer 20, respectively. R5 is the thermal resistance of the heat spreader 18. R2, R4, R6, and R8 represent the thermal resistance at the interfacial region of the components (e.g., contact resistances). In a typical cooling system, R3 and R7 may account for 80% or more of the cumulative thermal resistance of the heat transfer path 26, and R5 may account for 5% or more. R1 of the first device 14 and R2, R4, R6, and R8 of the interfaces account for the remaining cumulative thermal resistance. Accordingly, embodiments described herein provide for integrated cooling assemblies embedded within a device package. The embedded cooling assemblies shorten the thermal resistance path between a semiconductor device and a heat sink and reduce thermal communication between semiconductor devices disposed in the same device package, such as described in relation to the figures below.

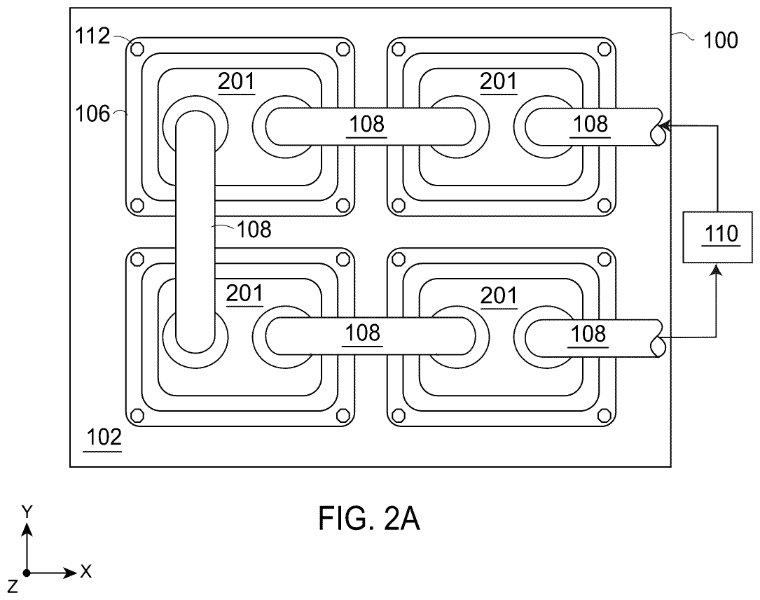

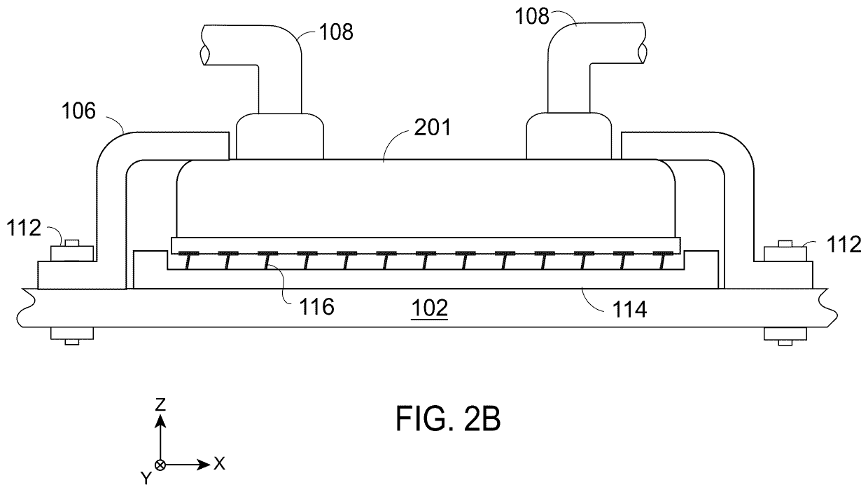

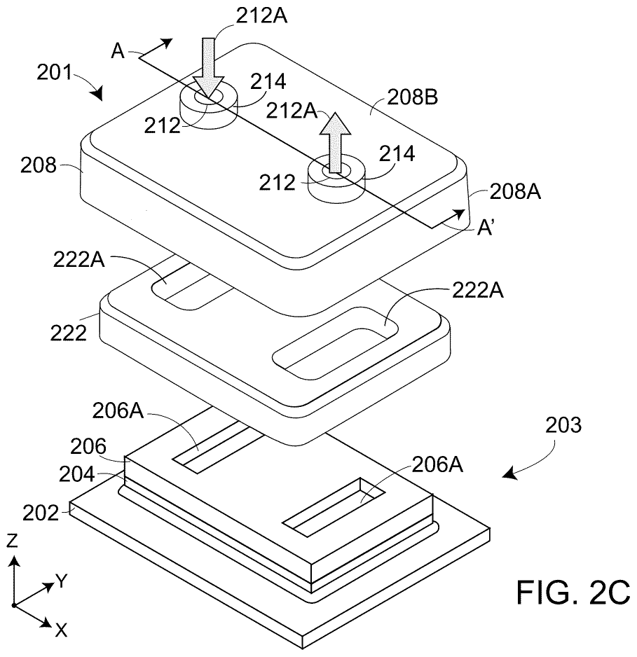

FIG. 2A is a schematic plan view of an example of a system panel 100, in accordance with embodiments of the present disclosure. Generally, the system panel 100 includes a printed circuit board (PCB) 102, a plurality of device packages 201 mounted to the PCB 102, and a plurality of coolant lines 108 fluidly coupling each of the device packages 201 to a coolant source 110. It is contemplated that coolant fluid may be delivered to each of the device packages 201 in any desired fluid phase, e.g., liquid, vapor, gas, or combinations thereof and may flow out from each device package 201 in the same phase or a different phase. In some embodiments, the coolant fluid is delivered to the device packages 201 and returned therefrom as a liquid, whereby the coolant source 110 may comprise a heat exchanger or chiller to maintain the coolant fluid at a desired temperature. In other embodiments, the coolant fluid may be delivered to the device packages 201 as a liquid, vaporized to a vapor within the device packages 201, and returned to the coolant source 110 as a vapor. In those embodiments, the device packages 201 may be fluidly coupled to the coolant source 110 in parallel, and the coolant source 110 may include or further include a compressor (not shown) for condensing the received vapor to a liquid form.

FIG. 2B is a schematic partial sectional side view of a portion of the system panel 100 of FIG. 2A. As shown, each device package 201 is fluidly coupled to the plurality of coolant lines 108 and is disposed in a socket 114 of the PCB 102 and connected thereto using a plurality of pins 116, or by other suitable connection methods, such as solder bumps (not shown). The device package 201 may be seated in the socket 114 and secured to the PCB 102 using a mounting frame 106 and a plurality of fasteners 112, e.g., compression screws, collectively configured to exert a relatively uniform downward force on the upward facing edges of the device package 201. The uniform downward force ensures proper pin contact between the device package 201 and the socket 114.

FIG. 2C is a schematic exploded isometric view of an example device package 201, in accordance with embodiments of the present disclosure. Generally, the device package 201 includes a package substrate 202, an integrated cooling assembly 203 disposed on the package substrate 202, and a package cover 208 disposed on a peripheral portion of the package substrate 202. Suitable materials that may be used in the package cover 208 include copper, aluminum, metal alloys, etc. The package cover 208 extends over the integrated cooling assembly 203 so that the integrated cooling assembly 203 is disposed between the package substrate 202 and the package cover 208. The integrated cooling assembly 203 typically includes a semiconductor device 204 and a cold plate 206 bonded to the semiconductor device 204. In some embodiments, the cold plate 206 may comprise substrate material like silicon, glass, ceramic, etc. Although the lateral dimensions (or footprint) of the cold plate 206 are shown to be the same or similar to the lateral dimensions (or footprint) of the semiconductor device 204, the footprint of the cold plate 206 may be smaller or larger in one or both directions when compared to the footprint of the semiconductor device 204.

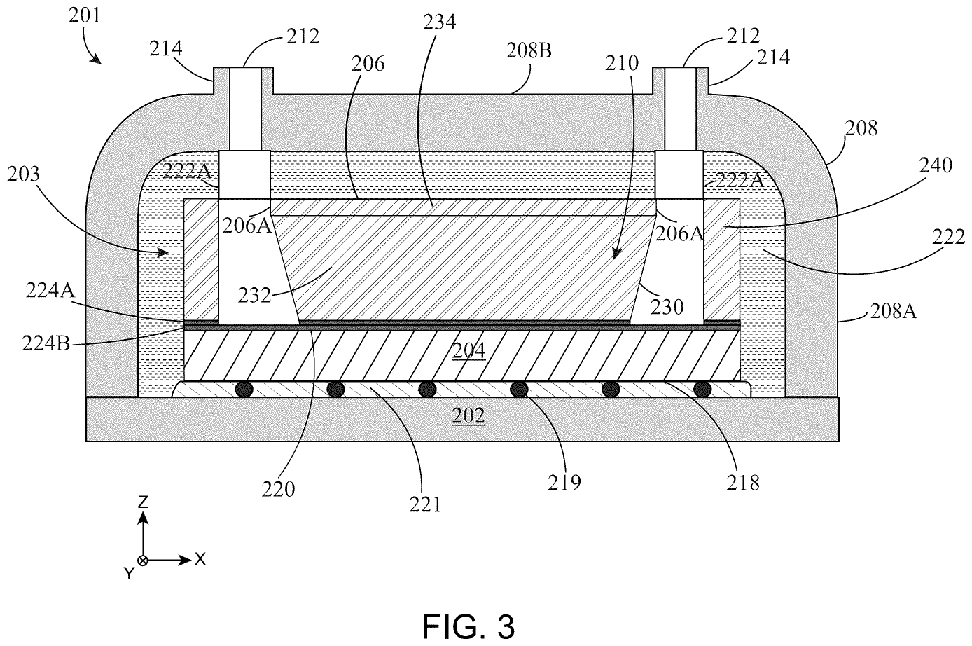

As shown, the device package 201 further includes a sealing material layer 222 that forms a coolant fluid impermeable barrier between the package cover 208 and the integrated cooling assembly 203 that prevents leaking of the coolant fluid outside of the cooling assembly and prevents coolant fluid from reaching an active side 218 (discussed below in relation to FIG. 3) of the semiconductor device 204 and causing damage thereto. In some embodiments, the sealing material layer 222 comprises an adhesive material that reliably attaches the package cover 208 to the integrated cooling assembly 203. In some embodiments, the sealing material layer 222 comprises a polymer or epoxy material that extends upwardly from the package substrate 202 to encapsulate and/or surround at least a portion of the semiconductor device 204. In some embodiments, the sealing material layer 222 may also comprise conductive material, e.g., solder. In other embodiments, the sealing material layer 222 is formed from a molding compound, e.g., a thermoset resin, that when polymerized, forms a hermetic seal between the package cover 208 and the cold plate 206. Here, the coolant fluid is delivered to the cold plate 206 through openings 222A disposed through the sealing material layer 222. As shown, the openings 222A are respectively in registration and fluid communication with inlet and outlet openings 212 of the package cover 208 thereabove and inlet and outlet openings 206A in the cold plate 206 therebelow.

It will be understood that the openings are shown in a section view. The openings may have any cross-sectional shape that allows fluid to flow therethrough (e.g., rectangular, square, hexagonal, or circular cross-sections). For example, the inlet and outlet openings 206A of the cold plate 206 may form an elongated shape extending from one side of the cold plate 206 to another side of the cold plate 206. For example, the inlet and outlet openings 206A may form any shape having a length greater than a width in the X-Y plane (e.g., a rectangular or a trapezoidal shape). A shape in the X-Y plane of the openings 222A disposed through the sealing material layer 222 may be substantially the same as the shape of the inlet and outlet openings 206A of the cold plate 206 in the same place. Furthermore, it will be understood that all references to an opening throughout the present disclosure refer to an opening defined by a sidewall (e.g., opening sidewall).

Generally, the package substrate 202 includes a rigid material, such as an epoxy or resin-based laminate, that supports the integrated cooling assembly 203 and the package cover 208. The package substrate 202 may include conductive features disposed in or on the rigid material that electrically couples the integrated cooling assembly 203 to a system panel, such as the PCB 102.

FIG. 3 is a schematic sectional view in the X-Z plane of the device package 201 taken along line A-A′ of FIG. 2C. As illustrated in FIG. 3, the semiconductor device 204 includes the active side 218 that includes device components, e.g., transistors, resistors, and capacitors, formed thereon or therein, and a non-active side, here the semiconductor device backside 220, opposite the active side 218. As shown, the active side 218 is positioned adjacent to and facing towards the package substrate 202. The active side 218 may be electrically connected to the package substrate 202 by use of conductive bumps 219, which are encapsulated by a first underfill layer 221 disposed between the semiconductor device 204 and the package substrate 202. The first underfill layer 221 may comprise a cured polymer resin or epoxy, which provides mechanical support to the conductive bumps 219 and protects against thermal fatigue. In some embodiments, the active side 218 may be electrically connected to another package substrate, another active die, or another passive die (e.g., interposer) using hybrid bonding or conductive bumps 219. The cold plate 206 may be disposed above the package substrate 202 with the semiconductor device 204 disposed therebetween. For example, the semiconductor device 204 (and the first underfill layer 221) may be disposed between the cold plate 206 and the package substrate 202. In some embodiments, the cold plate 206 may be disposed directly on the package substrate 202.

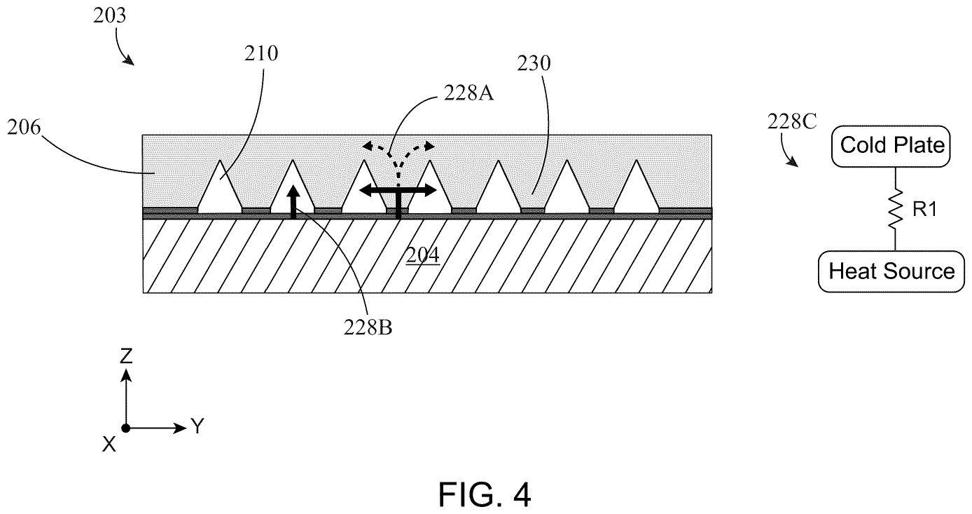

Here, the cold plate 206 comprises a top portion 234 and a sidewall 240 (e.g., a perimeter sidewall defining a perimeter of the cold plate 206) extending downwardly from the top portion 234 to the backside 220 of the semiconductor device 204. The top portion 234, the perimeter sidewall 240, and the backside 220 of the semiconductor device 204 collectively define a coolant channel 210 therebetween. The cold plate 206 comprises cavity dividers (e.g., support features 230) extending downwardly from the top portion 234 towards the backside 220 of the semiconductor device 204. The cavity dividers (e.g., support features 230) may extend laterally and in parallel between an inlet opening 206A of the cold plate 206 and an outlet opening 206A of the cold plate 206 to define coolant channels 210 therebetween. It should be appreciated that, the cold plate 206 may comprise one cavity divider (e.g., a support feature 230) which forms two coolant channels (e.g., one coolant channel on either side of the cavity divider) by means of the cavity divider (e.g., the support feature 230) and portions of the perimeter sidewall 240. More specifically, coolant channels 210 may be formed between the cavity divider (e.g., the support feature 230) and a portion of the perimeter sidewall 240 extending parallel to the cavity divider (e.g., the support feature 230). Alternatively, in other embodiments, the cold plate 206 may comprise plural cavity dividers (e.g., support features 230), for example two cavity dividers, five cavity dividers, or six cavity dividers (as illustrated in FIG. 4). In such examples, the cold plate 206 comprises more than two coolant channels 210, for example three coolant channels, four coolant channels, seven coolant channels, or more, defined between the cavity dividers (e.g., support features 230) and/or the cavity divider(s) (e.g., at least one of the support features 230) and the perimeter sidewall 240.

The cavity dividers (e.g., support features 230) comprise cavity sidewalls 232 which form surfaces of corresponding coolant channels 210. In embodiments where plural cavity dividers (e.g., support features 230) extend in parallel to each other, cavity sidewalls 232 of adjacent cavity dividers (e.g., adjacent ones of the support features 230) are opposite (e.g., facing) each other. In embodiments comprising a single cavity divider (e.g., one support feature 230), a first cavity sidewall may be opposite (e.g., face) a first portion of the perimeter sidewall 240 extending parallel to and facing the first cavity sidewall. A second cavity sidewall may be opposite (e.g., face) a second portion of the perimeter sidewall 240 extending parallel to and facing the second cavity sidewall. The first portion of the perimeter sidewall 240 may be an opposite side of the cold plate 206 to the second portion of the perimeter sidewall 240. For example, in embodiments where the cold plate 206 is rectangular, first and second opposing sides of the rectangular cold plate 206 form the first and second portions of the perimeter sidewall 240.

The cavity dividers (e.g., support features 230) may be continuous cavity dividers which extend continuously (e.g., in the Y-axis direction) between the inlet opening 206A and the outlet opening 206A of the cold plate 206.

With reference to FIG. 3, coolant channels 210 may be defined by:
the backside 220 of the semiconductor device 204, which forms lower coolant channel surfaces;
portions of the perimeter sidewall 240 extending in the Y-axis direction, which form end surfaces of the coolant channels 210;
the cavity sidewalls 232, which form inner surfaces of the coolant channels 210 in the X-axis direction; and
portions of the perimeter sidewall 240 extending in the X-axis direction, which form outer surfaces of the coolant channels 210 in the X-axis direction.

Here, the cavity sidewalls 232 are formed at an acute angle with respect to the backside 220 of the semiconductor device 204 such that upper portions of opposing (e.g., facing) cavity sidewalls 232 meet. Therefore, the cavity sidewalls 232 and the backside 220 of the semiconductor device 204 collectively define a triangular cross-section of the coolant channel 210.

In some embodiments, the backside 220 of the semiconductor device 204 comprises a corrosion protective layer (not shown). The corrosion protective layer may be a continuous layer disposed across the entire backside 220 of the semiconductor device 204, such that the cold plate 206 is attached thereto. Beneficially, the corrosion protective layer provides a corrosion-resistant barrier layer, thus preventing undesired corrosion of the semiconductor device 204 (e.g., the semiconductor substrate material which might otherwise be in direct contact with coolant fluid flowing through a coolant chamber volume 210).

One or more coolant chamber volumes may include one or more coolant channels. The coolant channels may extend between a single inlet opening and a single outlet opening of the cold plate 206, such that the coolant chamber volume(s) and/or coolant channel(s) share the same inlet and outlet openings. In some embodiments, multiple inlet and/or outlet openings may be coupled to the coolant chamber volume(s).

In embodiments having plural coolant chamber volumes and/or plural coolant channels, each coolant chamber volume and/or coolant channel may be connected between a separate inlet opening and a separate outlet opening. In such embodiments, the coolant fluid may be directed to the separate inlet openings and from the separate outlet openings using a manifold disposed above the openings in the Z-axis direction.

In some embodiments, a height in the Z-axis direction of the coolant chamber volume(s) and or coolant channel(s) may be greater than 100 μm, 100 μm-1000 μm, or 100 μm-700 μm. A width in the Y-axis direction of the coolant chamber volume(s) and/or coolant channel(s) may be greater than 100 μm, 100 μm-1000 μm, or 100 μm-700 μm. For example, the width of the coolant chamber volume(s) and/or coolant channel(s) may be greater than the height. A cross-section of the coolant chamber volume(s) and/or coolant channel(s) in the Y-Z plane is wide enough to allow for a pressure drop of 0-20 psi, 3-15 psi, or 4-10 psi.

In some embodiments, preparing a desired surface roughness of the sidewalls of the coolant chamber volume(s) and/or coolant channels may include depositing an organic layer on a photoresist layer after cold plate features have been etched to form a micro-masking layer, such as between 1 to 30 nm. The micro-masking layer may be dry etched to form the desired surface roughness, such as between 0.1 to 3.0 nm.

With reference to FIG. 3, the cold plate 206 is attached to the backside 220 of the device 204 without the use of an intervening adhesive. For example, the cold plate 206 may be directly bonded to the backside 220 of the device 204, such that the cold plate 206 and the backside 220 of the device 204 are in direct contact. For example, in some embodiments, one or both of the cold plate 206 and the backside 220 of the semiconductor device 204 may comprise a dielectric material layer, e.g., a first dielectric material layer 224A and a second dielectric material layer 224B respectively, and the cold plate 206 is directly bonded to the backside 220 of the semiconductor device 204 through bonds formed between the dielectric material layers 224A, 224B. In some embodiments, one of the cold plate 206 or the backside 220 of the semiconductor device 204 may comprise a thin bonding dielectric layer (e.g., silicon nitride, etc.) and other element(s) may not include any such explicit bonding dielectric layer (or can have only a native oxide layer). The first and second dielectric material layers 224A, 224B may be continuous or non-continuous. For example, the first dielectric material layer 224A may be disposed only on lower surfaces of the cold plate 206 facing the backside 220 of the semiconductor device 204. With reference to FIG. 4, described below, portions of the first dielectric material layer 224A may be disposed only on lower surfaces of support features 230. Beneficially, directly bonding the cold plate 206 to the semiconductor device 204, as described above, reduces the thermal resistance therebetween and increases the efficiency of heat transfer from the semiconductor device 204 to the cold plate 206. In particular, thermal resistance is reduced by directly bonding lower surfaces of the cavity dividers (e.g., support features 230) facing the semiconductor device 204 to the backside 220 of the semiconductor device 204.

FIG. 4 is a schematic sectional view in the Y-Z plane of the integrated cooling assembly 203. In FIG. 4, the cold plate 206 comprises a patterned side that faces towards the semiconductor device 204 and an opposite side that faces towards the package cover 208 (not shown). The patterned side comprises a coolant chamber volume having plural coolant channels 210, which extend laterally between the inlet and outlet openings of the cold plate 206. Each coolant channel 210 comprises cavity sidewalls that define a corresponding coolant channel 210. Portions of the cold plate 206 between the cavity sidewalls form support features 230. The support features 230 provide structural support to the integrated cooling assembly 203 and disrupt laminar fluid flow at the interface of the coolant and the device backside 220, resulting in increased heat transfer therebetween. Furthermore, by introducing plural coolant channels 210 to define separate coolant flow paths, an internal surface area of the cold plate 206 is increased, which further increases the efficiency of heat transfer.

In FIG. 4, arrows 228A and 228B illustrate two different heat transfer paths in the integrated cooling assembly 203. A first heat transfer path illustrated by arrow 228B shows heat generated by the semiconductor device 204 transferring directly from the semiconductor material of the semiconductor device 204 to coolant fluid flowing through the cold plate 206. A second heat transfer path illustrated by arrows 228A shows heat generated by the semiconductor device 204 being transferred from semiconductor material (e.g., silicon material) of the semiconductor device 204 to semiconductor material (e.g., silicon material) of the cold plate 206 structure, propagated throughout the semiconductor material of the cold plate 206 structure (shown as dashed lines), and being transferring into coolant fluid flowing through the cold plate 206. A thermal resistance of the first and second heat transfer paths 228A, 228B is illustrated by heat transfer path 228C, which is shown as thermal resistance R1 between a heat source and a cold plate. Here, R1 is the thermal resistance of the bulk semiconductor material of the semiconductor device 204. It can be seen that the heat transfer path 228C of the integrated cooling assembly 203 is reduced compared to the heat transfer path 26 of the device package 10 of FIG. 1, due to the direct bonding discussed above.

In some embodiments, the cold plate 206 may be attached to the semiconductor device 204 using a hybrid bonding technique, where bonds are formed between the dielectric material layers 224A, 224B (see FIG. 3) and between metal features, such as between first metal pads and second metal pads, disposed in the dielectric material layers 224A, 224B.

Suitable dielectrics that may be used as the dielectric material layers 224A, 224B include silicon oxides, silicon nitrides, silicon oxynitrides, silicon carbon nitrides, metal-oxides, metal-nitrides, silicon carbide, silicon oxycarbides, silicon oxycarbonitride, diamond-like carbon (DLC), or combinations thereof. In some embodiments, one or both of the dielectric material layers 224A, 224B are formed of an inorganic dielectric material, e.g., a dielectric material substantially free of organic polymers. Typically, one or both of the dielectric layers are deposited to a thickness greater than the thickness of a native oxide, such as about 1 nanometer (nm) or more, 5 nm or more, 10 nm or more, 50 nm or more, or 100 nm or more. In some embodiments, one or both of the layers are deposited to a thickness of 3 micrometers or less, 1 micrometer or less, 500 nm or less, such as 100 nm or less, or 50 nm or less. The dielectric layer material and thickness may be optimized for lower thermal resistance between the die and the cold plate. For example, a first dielectric material layer comprising native oxide, the first dielectric material layer having a thickness in the Z-direction of about 1 nm to about 5 nm, may be disposed on a semiconductor substrate (e.g., silicon). The first dielectric material layer comprising the native oxide may be directly bonded to a second dielectric material layer comprising a same or different dielectric material, the second dielectric material layer having a thickness in the Z-direction of about 1 nm to about 5 nm. That is, a bonding layer comprising native oxide may be bonded to another bonding layer comprising a native oxide or another dielectric material.

The cold plate 206 may be formed of any suitable material that has sufficient structural strength to withstand the desired pressures of coolant flowing into the coolant chamber volume 210. For example, the cold plate 206 may be formed of semiconductor material like silicon or other engineered materials like glass. In other examples, the cold plate 206 may be formed of a material selected from a group comprising polymers, metals, ceramics, or composites thereof. In some embodiments, the cold plate 206 may be formed of stainless steel (e.g., from a stainless-steel metal sheet) or a sapphire plate.

In some embodiments, the cold plate 206 may be formed of a bulk material having a substantially similar coefficient of linear thermal expansion (CTE) to the bulk material of the substrate 202 and/or the semiconductor device 204, where the CTE is a fractional change in length of the material (in the X-Y plane) per degree of temperature change. In some embodiments, the CTEs of the cold plate 206, the substrate 202, and/or the semiconductor device 204 are matched so that the CTE of the substrate 204 and/or the semiconductor device 204 is within about +/−20% or less of the CTE of the cold plate 206, such as within +/−15% or less, within +/−10% or less, or within about +/−5% or less when measured across a desired temperature range. In some embodiments, the CTEs are matched across a temperature range from about −60° C. to about 100° C. or from about −60° C. to about 175° C. In one example embodiment, the matched CTE materials each include silicon.

In some embodiments, the cold plate 206 may be formed of a material having a substantially different CTE from the semiconductor device 204, e.g., a CTE mismatched material. In such embodiments, the cold plate 206 may be attached to the semiconductor device 204 by a compliant adhesive layer (not shown) or a molding material that absorbs the difference in expansion between the cold plate 206 and the semiconductor device 204 across repeated thermal cycles.

The package cover 208 shown in FIGS. 2C and 3 generally comprises one or more vertical or sloped sidewall portions 208A and a lateral portion 208B that spans and connects the sidewall portions 208A. The sidewall portions 208A may extend upwardly from a peripheral surface of the package substrate 202 to surround the device 204 and the cold plate 206 disposed thereon. The lateral portion 208B may be disposed over the cold plate 206 and is typically spaced apart from the cold plate 206 by a gap corresponding to the thickness of the sealing material layer 222. Coolant is circulated through the coolant chamber volume 210 through the inlet and outlet openings 212 of the package cover 208 formed through the lateral portion 208B. The inlet and outlet openings 206A of the cold plate 206 may be in fluid communication with the inlet and outlet openings 212 of the package cover 208 through the inlet and outlet openings 222A formed in the sealing material layer 222 disposed therebetween. In certain embodiments, coolant lines 108 (FIGS. 2A-2B) may be attached to the device package 201 by use of connector features formed in the package cover 208, such as threads formed in the sidewalls of the inlet and outlet openings 212 and/or protruding features 214 that surround the inlet and outlet openings 212 and extend upwardly from a surface of the lateral portion 208B.

Typically, the package cover 208 is formed of semi-rigid or rigid material so that at least a portion of the downward force exerted on the package cover 208 by the mounting frame is transferred to a supporting surface of the package substrate 202 and not transferred to the cold plate 206 and the semiconductor device 204 therebelow. In some embodiments, the package cover 208 is formed of a thermally conductive metal, such as aluminum or copper. In such embodiments, the package cover 208 functions as a heat spreader that redistributes heat from one or more electronic components of the semiconductor device 204.

It should be noted that the direction in which the coolant fluid flows through the cold plate 206 may be controlled depending on the relative locations of the inlet and outlet openings. For example, the coolant fluid may flow from left to right in the device package 201 of FIG. 3 when the inlet openings 212, 222A, 206A of the package cover 208, the sealing material layer 222, and the cold plate 206, respectively, are located on the left-hand side of the device package 201 and the outlet openings 212, 222A, 206A of the package cover 208, the sealing material layer 222, and the cold plate 206, respectively, are located on the right-hand side of the device package 201. Alternatively, the coolant fluid may flow from right to left in the device package 201 illustrated in FIG. 3 when the outlet openings 212, 222A, 206A of the package cover 208, the sealing material layer 222, and the cold plate 206 are located on the left-hand side of the device package 201 and the inlet openings 212, 222A, 206A of the package cover 208, the sealing material layer 222, and the cold plate 206 are located on the right-hand side of the device package 201. Although only one set of inlet and outlet openings is shown and described here, additional inlet and outlet openings may also be provided at various locations on the package cover 208, the sealing material layer 222, and the cold plate 206.

An example flow path of the coolant fluid through the coolant chamber volume 210 may be as follows:
1. Coolant fluid enters the coolant chamber volume 210 through the inlet openings.
2. Coolant fluid flows across the inside surfaces of the cold plate 206 and absorbs heat generated by the semiconductor device 204, which has dissipated into the cold plate 206 structure. The coolant fluid may also flow directly across the backside 220 of the semiconductor device 204 to absorb heat energy directly from the semiconductor device 204. The coolant chamber volume 210 may additionally have various channels formed to direct the coolant fluid flow from inlet opening(s) to outlet opening(s) and facilitate heat extraction from the semiconductor device 204 by the coolant fluid. In some embodiments, the coolant fluid may be in direct contact with the backside 220 of the semiconductor device 204 or via one or more substrate or layers between the coolant fluid or backside 220 of the semiconductor device 204.
3. Coolant fluid exits the coolant chamber volume 210 through outlet openings.

It will be understood from the above flow path that heat is extracted without introducing an unnecessary thermal resistance (e.g., a TIM disposed between the backside 220 of the semiconductor device 204 and the cold plate 206) between the backside 220 of the semiconductor device 204 and the cold plate 206.

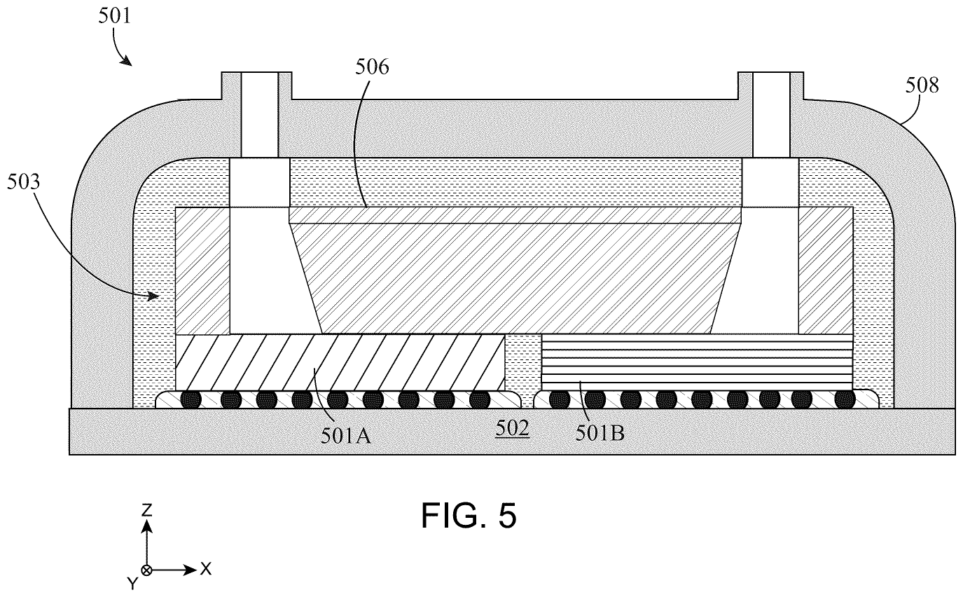

FIG. 5 is a schematic side sectional view in the X-Z plane of an example of a multi-component device package 501 that includes a cold plate 506 directly bonded to the backside surfaces of two or more devices 501A, 501B. The multi-component device package 501 may be similar to the device package 201 described above, and therefore the description of similar features is omitted for brevity. In some embodiments, the two or more devices 501A and 501B are reconstituted and then bonded to the cold plate 506. As shown, the device package 501 includes a package substrate 502, an integrated cooling assembly 503 and a package cover 508. The integrated cooling assembly 503 may include a plurality of devices 501A (one shown) that may be singulated and/or disposed in a vertical device stack 501B (one shown). The cold plate 506 may be attached to each of the devices 501A and device stack 501B, e.g., by the direct bonding methods described herein or other methods including flip chip bonding, etc. In some embodiments, the device 501A may comprise a processor, and the device stack 501B may comprise a plurality of memory devices. Here, the device 501A and the device stack 501B are disposed in a side-by-side arrangement on the package substrate 502 and are in electrical communication with one another through conductive elements formed in, on, or through the package substrate 502. Here, the cold plate 506 is sized to provide a bonding surface for attachment to both the device 501A and the device stack 501B but may otherwise be the same or substantially similar to other cold plates described herein. In some embodiments, the lateral dimensions (or footprint) of the cold plate 506 may be smaller or larger than the combined lateral dimensions (or footprint) of both the device 501A and the device stack 501B. In some embodiments, one or more sidewalls of the cold plate 506 may be aligned or offset to the vertical sidewalls of the device 501A and the device stack 501B (including inside or outside their footprint). In some embodiments, more than one cold plate 506 may be bonded. For example, separate cold plates may be bonded to the device 501A and the device stack 501B.

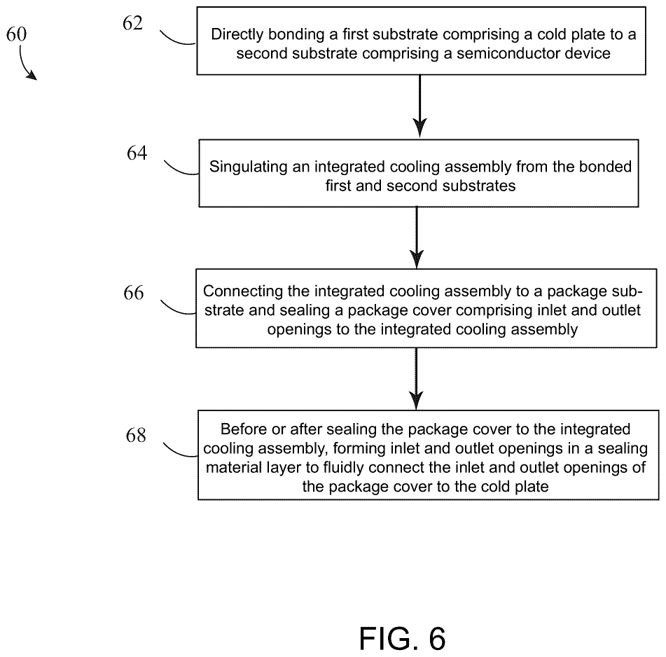

FIG. 6 is a flow diagram showing a method 60 of forming an integrated cooling assembly, according to embodiments of the present disclosure. Generally, the method 60 includes bonding a first substrate comprising one or more cold plates 206 to a second substrate comprising one or more semiconductor devices 204, and singulating one or more integrated cooling assemblies 203 from the bonded first and second substrates. For example, a wafer (bare or reconstituted wafer) comprising one or more cold plates 206 can be directly bonded to another wafer (bare or reconstituted wafer) comprising one or more semiconductor devices 204.

It will be understood that the first substrate may be a cold plate die or part of a wafer of cold plates. Further, the second substrate may be a semiconductor device die or part of a wafer of semiconductor devices 204. Therefore, the method 60 may include die-to-die direct bonding (e.g., cold plate die to semiconductor device die), wafer-to-die direct bonding (e.g., cold plate die to semiconductor device wafer, or cold plate wafer to semiconductor device die), and wafer-to-wafer direct bonding (e.g., cold plate wafer to semiconductor device wafer). It will be understood that the singulation step (discussed in relation to block 64, below) may not be required for a die-to-die direct bonding operation.

For simplicity, the following description is focused on forming one integrated cooling assembly 203 comprising one cold plate 206 and one semiconductor device 204. However, as mentioned above, in some embodiments, the first substrate may comprise plural cold plates 206 and the second substrate may comprise plural semiconductor devices 204, such that plural integrated cooling assemblies 203 may be formed from the first and second substrates.

At block 62, the method 60 includes directly bonding the first substrate (e.g., a monocrystalline silicon wafer) comprising a cold plate 206 to the second substrate (e.g., a monocrystalline silicon wafer) comprising a semiconductor device 204 without an intervening adhesive.

In some embodiments, the first substrate may be etched using a patterned mask layer formed on its surface to form features of the cold plate 206. An anisotropic etch process may be used, which uses inherently differing etch rates for the silicon material as between {100} plane surfaces and {111} plane surfaces when exposed to an anisotropic etchant.

In some embodiments, the etching process is controlled to where the etch rates of the substrate surfaces have a ratio between about 1:10 and about 1:200, such as between about 1:10 and about 1:100, for example between about 1:10 and 1:50, or between about 1:25 and 1:75. Examples of suitable anisotropic wet etchants include aqueous solutions of potassium hydroxide (KOH), ethylene diamine and pyrocatechol (EPD), ammonium hydroxide (HN₄OH), hydrazine (N₂H₄), or tetra methyl ammonium hydroxide (TMAH). The actual etch rates of the silicon substrate depend on the concentration of the etchant in the aqueous solution, the temperature of the aqueous solution, and a concentration of the dopant in the substrate (if any). Typically, the mask layer is formed of a material that is selective to anisotropic etch compared to the underlying monocrystalline silicon substrate. Examples of suitable mask materials include silicon oxide (SiₓO_{y}) or silicon nitride (SiₓN_{y}). In some embodiments, the mask layer has a thickness of about 100 nm or less, such as about 50 nm or less, or about 30 nm or less. The mask layer may be patterned using any suitable combination of lithography and material etching patterning methods.

The second substrate may include a bulk material, and a plurality of material layers disposed on the bulk material. The bulk material may include any semiconductor material suitable for manufacturing semiconductor devices, such as silicon, silicon carbide, silicon germanium, germanium, group III-V semiconductor materials, group II-VI semiconductor materials, or combinations thereof. While some high-performance processors like CPUs, GPUs, neural processing units (NPUs), and tensor processing units (TPUs) are typically made out of silicon, some other high power density (hence substantial heat-generating) devices may comprise silicon carbide or gallium nitride, for example. In some embodiments, the second substrate may include a monocrystalline wafer, such as a silicon wafer, a plurality of device components formed in or on the silicon wafer, and a plurality of interconnect layers formed over the plurality of device components. In other embodiments, the second substrate may comprise a reconstituted substrate, e.g., a substrate formed from a plurality of singulated devices embedded in a support material. In some embodiments, each semiconductor device may have its own individual cold plate fabricated through a reconstitution process.

The bulk material of the second substrate may be thinned after the semiconductor device 204 is formed using one or more backgrinding, etching, and polishing operations that remove material from the backside. Thinning the second substrate may include using a combination of grinding and etching processes to reduce the thickness (in the Z-direction) to about 450 μm or less, such as about 200 μm or less, or about 150 μm or less or about 50 μm or less. After thinning, the backside 220 may be polished to a desired smoothness using a chemical mechanical polishing (CMP) process, and the dielectric material layer may be deposited thereon. In some embodiments, the dielectric material layer may be polished to a desired smoothness to prepare the second substrate for the bonding process. In some embodiments, the method 60 includes forming a plurality of metal features in the dielectric material layer in preparation for a hybrid bonding process, such as by use of a damascene process.

In some embodiments, the active side of the second substrate is temporarily bonded to a carrier substrate (not shown) before or after the thinning process. When used, the carrier substrate provides support for the thinning operation and/or for the thinned material to facilitate substrate handling during one or more of the subsequent manufacturing operations described herein.

Here, the method 60 may include forming dielectric layers on one or both the first and second substrates, and directly bonding includes forming dielectric bonds between a first dielectric material layer of the first substrate and a second dielectric material layer of the second substrate (or forming dielectric bonds between one substrate and a dielectric material layer of the other substrate). Direct bonding processes join dielectric layers by forming strong chemical bonds (e.g., covalent bonds) between the dielectric layers.

Generally, directly bonding the surfaces (of the dielectric material layers formed on the first and second substrates) includes preparing, aligning, and contacting the surfaces. Examples of dielectric material layers include silicon oxide, silicon nitride, silicon oxynitride, and silicon carbonitride. Preparing the surfaces may include smoothing the respective surfaces to a desired surface roughness, such as between 0.1 to 3.0 nm RMS, activating the surfaces to weaken or open chemical bonds in the dielectric material, and terminating the surfaces with a desired species. Smoothing the surfaces may include polishing the first and second substrates using a CMP process. Activating and terminating the surfaces with a desired species may include exposing the surfaces to radical species formed in a plasma. The bond interface between the bonded dielectric layers can include a higher concentration of materials from the activation and/or last chemical treatment processes compared to the bulk of the bonding layers. For example, in some embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces.

In some embodiments, the plasma is formed using a nitrogen-containing gas, e.g., N₂, and the terminating species includes nitrogen, or nitrogen and hydrogen. In some embodiments, fluorine may also be present within the plasma. In some embodiments, the surfaces may be activated using a wet cleaning process, e.g., by exposing the surfaces to an aqueous ammonia solution. In some embodiments, the dielectric bonds may be formed using a dielectric material layer deposited on only one of the first and second substrates, but not on both. In those embodiments, the direct dielectric bonds may be formed by contacting the deposited dielectric material layer of one of the first and second substrates directly with a bulk material surface (or such a surface with a native oxide) of the other substrate.

Directly forming direct dielectric bonds between the first and second substrates at block 62 may include bringing the prepared and aligned surfaces into direct contact at a temperature less than 150° C., such as less than 100° C., for example, less than 30° C., or about room temperature, e.g., between 20° C. and 30° C. Without intending to be bound by theory, in the case of directly bonding surfaces terminated with nitrogen and hydrogen (e.g., NH₂ groups), it is believed that the hydrogen terminating species diffuse from the interfacial bonding surfaces, and chemical bonds are formed between the remaining nitrogen species during the direct bonding process. In some embodiments, the direct bond is strengthened using an anneal process, where the substrates are heated to and maintained at a temperature of greater than about 30° C. and less than about 450° C., for example, greater than about 50° C. and less than about 250° C., or about 150° C., for a duration of about 5 minutes or more, such as about 15 minutes. Typically, the bonds will strengthen over time even without the application of heat. Thus, in some embodiments, the method does not include heating the substrates.

In embodiments where the first and second substrates are bonded using hybrid dielectric and metal bonds, the method 60 may further include planarizing or recessing the metal features below the dielectric field surface before contacting and bonding the dielectric material layers. After the dielectric bonds are formed, the first and second substrates may be heated to a temperature of 150° C. or more and maintained at the elevated temperature for a duration of about 1 hour or more, such as between 8 and 24 hours, to form direct metallurgical bonds between the metal features.

Suitable direct dielectric and hybrid bonding technologies that may be used to perform aspects of the methods described herein include ZiBond® and DBI®, each of which are commercially available from Adeia Holding Corp., San Jose, CA, USA.

At block 64, the method 60 includes singulating at least one integrated cooling assembly 203 from the bonded first and second substrates. Singulation after bonding may impart distinctive structural characteristics on the integrated cooling assembly 203 as the bonding surface of the cold plate 206 has the same perimeter as the backside of the semiconductor device 204 bonded thereto. Thus, the sidewalls (e.g., side surfaces) of the cold plate 206 are typically flush with the edges (e.g., side surfaces) of the semiconductor device 204 about their common perimeters. In some embodiments, the cold plate 206 is singulated from the first substrate using a process that cuts or divides the first substrate in a vertical plane, i.e., in the Z-direction. In those embodiments, the side surfaces of the cold plate 206 are substantially perpendicular to the backside 220 of the semiconductor device 204, i.e., a horizontal (X-Y) plane of an attachment interface between the semiconductor device 204 and the cold plate 206. In some embodiments, the cold plate 206 is singulated using a saw or laser dicing process.

At block 66, the method 60 may include connecting the integrated cooling assembly 203 to the package substrate 202 and sealing a package cover 208 comprising inlet and outlet openings 212 to the integrated cooling assembly 203 by use of a molding compound that, when cured, forms a sealing material layer 222.

At block 68, the method 60 may include, before or after sealing the package cover 208 to the integrated cooling assembly 203, forming inlet and outlet openings 222A in the sealing material layer 222 to fluidly connect the inlet and outlet openings 212 of the package cover 208 to the cold plate 206.

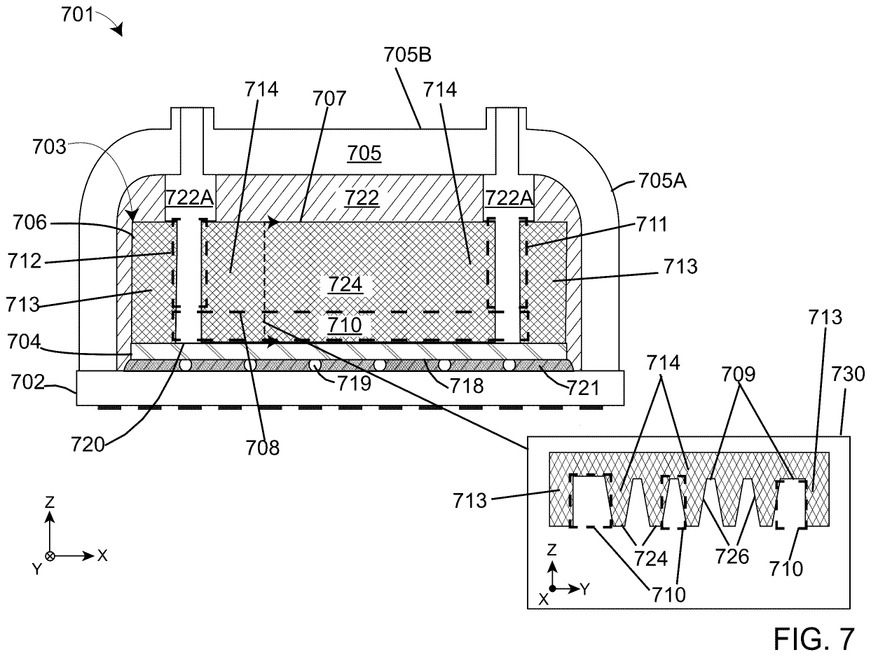

FIG. 7 is a schematic sectional side view of the device package 701 comprising an integrated cooling assembly 703, in accordance with some embodiments of the present disclosure. FIG. 7 illustrates a side view of the device package 701 in the X-Z plane, such as viewed along the line A-A′ of FIG. 2C. Here, the integrated cooling assembly 703 comprises a cold plate 706 with protruding features (e.g., protrusions 724). FIG. 7 further illustrates an inset 730 showing the side view of the cold plate 706 in the Y-Z plane. Here, the device package 701 includes a package substrate 702, an integrated cooling assembly 703 disposed on the package substrate 702, and a package cover 705 disposed on a peripheral portion of the package substrate 702. The package cover 705 extends over the integrated cooling assembly 703 so that the integrated cooling assembly 703 is disposed between the package substrate 702 and the package cover 705. The package cover 705 may be sealingly attached. As shown, the device package 701 further includes a sealing material layer 722 that forms a coolant impermeable barrier between the package cover 705 and the integrated cooling assembly 703. Coolant fluid may be delivered to the integrated cooling assembly 703 via respective inlet and outlet openings of the package cover 705 and corresponding openings 722A disposed through the sealing material layer 722. Here, the coolant fluid continues through one or more coolant channels of the integrated cooling assembly 703 via an inlet opening 712, a coolant chamber volume 710, and an outlet opening 711 of the cold plate 706. The package substrate 702 may include a rigid material, such as an epoxy or resin-based laminate, that supports the integrated cooling assembly 703 and the package cover 705. The package substrate 702 may include conductive features disposed in or on the rigid material that electrically couple the integrated cooling assembly 703 to a system panel, such as the PCB 102.

The integrated cooling assembly 703 typically includes a semiconductor device, here device 704, and a cold plate 706 bonded to the device 704. Here, the device 704 includes an active side 718 that includes device components, e.g., transistors, resistors, and capacitors, formed thereon or therein, and a non-active side, here the device backside 720, opposite the active side 718. As shown, the active side 718 is positioned adjacent to and facing towards the package substrate 702. The active side 718 may be electrically connected to the package substrate 702 by use of conductive bumps 719, which are encapsulated by an underfill layer 721 disposed between the device 704 and the package substrate 702. The underfill layer 721 may comprise a cured polymer resin or epoxy, which provides mechanical support to the conductive bumps 719 and protects against thermal fatigue. Here, the cold plate 706 is disposed on the semiconductor device 704, and the semiconductor device 704 is attached to the package substrate 702. That is, the semiconductor device 704 may be disposed between the cold plate 706 and the package substrate 702.

The cold plate 706 generally includes a first side 707 that faces towards the package cover 705, a second side 708 opposite the first side and that faces towards the device 704, and cold plate sidewalls 713 extending downwardly from the second side to define a coolant chamber volume 710 therebetween when the cold plate 706 is attached to the device backside 720. The cold plate has inlet and outlet openings 712, 711 that may be substantially aligned with the openings 722A disposed through the sealing material layer 722, which in turn may be substantially aligned with respective inlet and outlet openings of the package cover 705, forming a flow path therethrough, such as when the coolant lines 108 are attached to the respective inlet and outlet openings of the package cover 705. One or more coolant chamber volumes, such as the coolant chamber volume 710, may extend between a single inlet opening and a single outlet opening of the cold plate 706, such that the coolant chamber volume(s) share the same inlet and outlet openings. In embodiments having plural coolant chamber volumes, each coolant chamber volume 710 may be connected between a separate inlet opening and a separate outlet opening. In such embodiments, a coolant fluid may be directed to the separate inlet openings and from the separate outlet openings using a manifold disposed above the openings in the Z-axis direction.

In some embodiments, the device backside 720 is in direct thermal contact with a coolant fluid flowed therethrough. One or both of the first and second sides of the cold plate 706 may be patterned and may be referred to as first and second patterned sides, respectively. The second patterned side forms a device facing cavity, here the coolant chamber volume 710, comprising a base surface 709 and the cold plate sidewalls 713 (e.g., outer sidewalls) that surround the base surface 709.

The second patterned side further includes a plurality of protrusions 724, such as fins, columns, or pillars, disposed inwardly of the cold plate sidewalls 713 and protrude downwardly from the base surface 709. Here, the plurality of protrusions 724 may correspond to cavity dividers, such as the support features 230. In some embodiments, one or more of the plurality of protrusions 724 are attached to the device 704, such as through direct bonding. When attached to the device 704 disposed therebelow, the base surface 709, the cold plate sidewalls 713, the protrusions 724, and the device backside 720 define the coolant channel and portions thereof, such as the inlet opening 712, the outlet opening 711, and the coolant chamber volume 710. Here, the base surface 709 forms an upper perimeter of the coolant chamber volume 710, the cold plate sidewalls 713 form outer perimeters of the coolant chamber volume 710, the protrusion sidewalls along the X-direction (X-direction protrusion sidewalls 726) form inner perimeters of the coolant chamber volume 710 along the X-direction, the protrusion sidewalls along the Y-direction (Y-direction protrusion sidewalls 714) form inner perimeters of the coolant chamber volume 710 along the Y-direction, and the device backside 720 forms a lower perimeter of the coolant chamber volume 710. As discussed herein, the cold plate sidewalls 713 that form the outer perimeters of the coolant chamber volume 710 may be alternatively referred to as outer sidewalls 713. The Y-direction protrusion sidewalls 714 that form the inner perimeters of the coolant chamber volume 710 may be alternatively referred to as inner sidewalls 714 (e.g., Y-direction inner sidewalls 714). The X-direction protrusion sidewalls 726 that form the inner perimeter of the coolant chamber volume 710 may be alternatively referred to as inner sidewalls 726 (e.g., X-direction inner sidewalls 726). Further as discussed below, the outer sidewalls 713 and the inner sidewalls 714 may define the inlet/outlet openings 712, 711 of the cold plate 706.

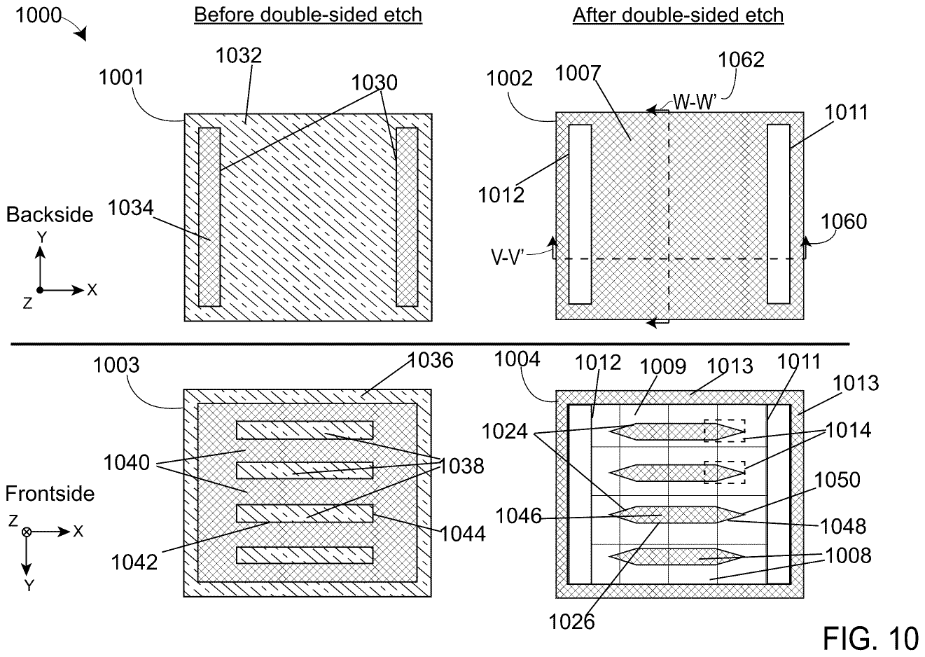

The cold plate 706 comprises the protrusions 724 disposed inwardly between the outer sidewalls 713. Each protrusion of the protrusions 724 comprises protrusion width sidewalls that extend in the Y-axis direction and define a width of the protrusions 724. The protrusion width sidewalls may also be referred to as Y-direction protrusion sidewalls. The protrusions 724 further comprise protrusion length sidewalls that extend in the X-direction and define a length of the protrusions 724. The protrusion length sidewalls may be referred to herein as X-direction protrusion sidewalls 726. Here, central segments of the X-direction protrusion sidewalls 726 are substantially parallel to form rectangular central segments of the protrusions 724 in the X-Y plane. Distal (e.g., end) segments of the X-direction protrusion sidewalls 726 are angled towards each other to form triangular distal segments of the protrusions 724 in the X-Y plane. The distal segments may be trapezoidal. That is, a planar protrusion sidewall may extend along the Y-direction between the distal segments of the X-direction protrusion sidewalls, forming the Y-direction protrusion sidewalls. In some embodiments, the angle of the distal segments of the X-direction protrusion sidewalls 726 towards each other may form distal segments having other shapes than triangular as described with respect to FIG. 10.

A width (in the Y-axis direction) between the X-direction protrusion sidewalls 726 at the central segments may be greater than a width (in the Y-axis direction) between the X-direction protrusion sidewalls 726 at the distal segments. Here, the rectangular central segments and the triangular distal segments may form protrusions 724 with a (convex) hexagonal shaped cross-section (e.g., an elongated diamond shape, as shown in FIG. 10) in the X-Y plane. It is noted that the central segments and the distal segments are not limited to forming a hexagonal shaped cross-section, such as an elongated diamond shape, and may form protrusions with any cross-sectional shape in the X-Y plane, such as when the angle of the distal segments of the X-direction protrusion sidewalls 726 towards each other form distal segments having other shapes than triangular as described with respect to FIG. 10. The X-direction protrusion sidewalls 726 and/or the Y-direction protrusion sidewalls 714 may slope away from the base surface 709 at an angle greater than 90°. As discussed above, the protrusions 724 comprise distal segments and a central segment extending between the distal segments. The central segment may have a surface at a lower surface of the protrusions 724. A width of the distal segments between protrusion sidewalls of the protrusions 724 may be less than a width of the central segment. Here, the X-direction sidewalls 726 include a first distal segment, a second distal segment, and a central segment extending therebetween. The first distal segment, the second distal segment, and the central segment extend along the X-direction as illustrated in FIG. 10. Here, the first distal segment and the second distal segment may be sloped with respect to the first side 707 (or the base surface 709) of the cold plate 706, and the central segment may be substantially parallel with respect to the first side 707 (or the base surface 709) of the cold plate 706.

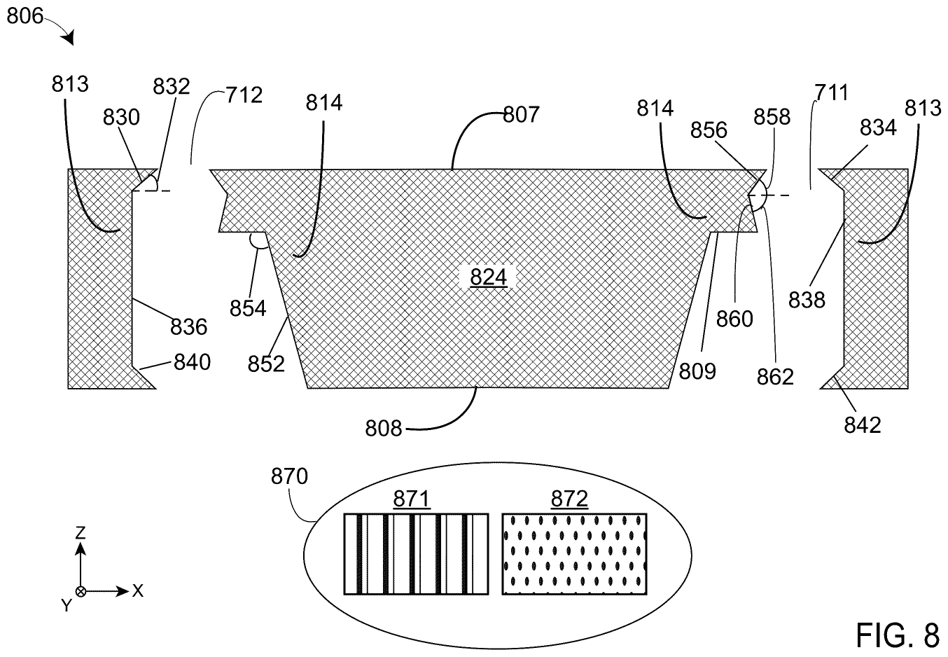

In some embodiments, sidewalls of the protrusions 724, such as the X-direction protrusion sidewalls 726 and/or the Y-direction protrusion sidewalls 714, may be sloped at angles ranging from about 45° to about 75°, such as about 65° or less, about 57° or less, about 52° or less, or about 47° or less. That is, the X-direction protrusion sidewalls 726, or segments thereof, may have angles in a range of about 50° to about 60°, such as about 52° to about 57°. Further, the Y-direction protrusion sidewalls 714, or segments thereof, may have angles in a range of about 50° to about 60°, such as about 52° to about 57°. It is noted that one or more sidewalls of the cold plate 706 are illustrated as extending vertically along the Z-direction (e.g., perpendicular to the X-direction, parallel to the X-Z plane or the Y-Z plane) in FIG. 7. It should be understood that these sidewalls, or at least segments thereof, may be sloped in some embodiments as described below with respect to FIG. 8. That is, the outer sidewalls 713, the inner sidewalls 714, and/or the X-direction protrusion sidewalls 726 may include a plurality of segments, where one or more of the plurality of segments slope away from the first side 707 at an angle greater than or less than 90°.

In some embodiments, the protrusions 724 have a width that traverses along the base surface 709. That is, the protrusions 724 may extend laterally between the inlet/outlet openings 712, 711. In some embodiments, the protrusions 724 extend starting from proximate to the inlet opening 712 and ending proximate to the opening 711. For example, one or more of the protrusions 724 may extend along the X-direction from a first opening of the inlet/outlet openings 712, 711 to a second opening of the inlet/outlet openings 712, 711 (e.g., starting from proximate to the right side of the left opening 712 and ending from proximate to the left side of the right opening 711). The protrusions 724 extend from the base surface 709 to a bonding interface with the device backside 720. The bonding interface may alternatively be referred to as a bonded interface. Beneficially, the protrusions 724 may provide structural support to the integrated cooling assembly 703. In one or more embodiments, the protrusions 724 extend from the base surface 709 to a height away from the device backside 720 to define a gap between lower surfaces of the protrusions 724 and the device backside 720.

Generally, the protrusions 724 disrupt laminar fluid flow at the interface of the coolant and the device backside 720, resulting in increased heat transfer therebetween. Furthermore, lower surfaces of the protrusions 724 are directly bonded to the backside 720 of the semiconductor device 704 such that heat (e.g., thermal flux) generated by the semiconductor device is absorbed by the protrusions 724. By thermally coupling the protrusions 724 to the backside 720 of the semiconductor device 704, the efficiency at which heat is transferred from the semiconductor device 704 to coolant fluid flowing through the coolant chamber volume 710 is increased. To further increase heat dissipation from the device 704, the protrusions 724 may comprise and/or be formed of a thermally conductive metal, such as copper. It is contemplated that each embodiment of the device packages described herein may include a cold plate having a patterned side, such as the second side 708, that comprises a base surface 709, cold plate sidewalls 713, and a plurality of the protrusions 724 without the explicit recitation thereof.

As discussed above, a plurality of openings, such as in the cold plate 706, in the sealing material layer 722, and in the package cover 705, may collectively define a flow path for coolant fluid. That is, coolant may be circulated through the coolant chamber volume 710 through openings disposed through the cold plate 706, shown here as inlet opening 712 and outlet opening 711, disposed between the downwardly facing base surface 709 and an opposite upwardly facing surface such as the first side 707. Here, the inlet opening 712, the outlet opening 711, and the coolant chamber volume 710 may be parts of a coolant channel through the cold plate 706 as illustrated in FIG. 3. The inlet opening 712 and the outlet opening 711 may both be formed between the opposite upwardly facing surface (i.e., the surface opposite the base surface 709) and the first side 707 of the cold plate 706. However, it will be understood that the inlet opening 712 and/or the outlet opening 711 may be formed on different surfaces of the cold plate 706. The inlet and outlet opening 712, 711 may be in fluid communication with respective inlet and outlet openings of the package cover 705 through openings 722A formed in the sealing material layer 722 disposed therebetween.

An example flow path of fluid through the coolant chamber volume 710 may be as follows:
1. Fluid enters the coolant chamber volume 710 through the inlet opening 712;
2. the fluid flows across the backside 720 of the semiconductor device 704 and flows across the inside surfaces of the cold plate 706 such that heat generated by the semiconductor device 704 is directly absorbed via the backside 720 and/or via the cold plate 706 after dissipation; and
3. the fluid exits the coolant chamber volume 710 through outlet opening 711.

Beneficially, the device package 701 provides for reduced thermal resistance in a heat transfer through the flow path when compared to thermal heat transfer path to an external heat sink.

As described in the methods below, in some embodiments, the cold plate 706 may be patterned using an anisotropic etch process that causes surfaces of the cold plate sidewalls 713 and the protrusions 724 to slope, e.g., to form an angle of greater than 90° with the base surface 709. The anisotropic etch process may cause the protrusions 724 to have a trapezoidal shape in cross section (e.g., in the X-Z plane and/or in the Y-Z plane) where each of the protrusions 724 may be wider at the base surface 709 than at its interface with the device 704. The cold plate sidewalls 713 may slope away from the base surface 709 (e.g., at an angle of greater than 90°) and are wider at the base surface 709 than at the interface with the device 704. In some embodiments, each of the protrusions 724 may be narrower at the base surface 709 than at its interface with the device 704. The cold plate sidewalls 713 may slope toward the base surface 709 (e.g., at an angle of less than 90°) and are narrower at the base surface than at the interface with the device 704. In some embodiments, the protrusions 724 do not have sloped sidewalls but vertical side walls. For example, the protrusions 724 may have a rectangular shape in cross section.

The sloped surface desirably increases the stability of the cold plate sidewalls 713 and protrusions 724 during manufacturing of the integrated cooling assembly 703. The added stability allows for the width of the field surfaces of the cold plate sidewalls 713 to be narrower, and the coolant channels to be deeper, when compared to cold plates having orthogonal surfaces, as narrow features at the base may undesirably buckle and break as the aspect ratio (height to width ratio) thereof is increased.

The package cover 705 generally comprises one or more vertical or sloped sidewall portions 705A and a lateral portion 705B that spans and connects the sidewall portions 705A. The sidewall portions 705A extend upwardly from a peripheral surface of the package substrate 702 to surround the device 704 and the cold plate 706 disposed thereon. The lateral portion 705B is disposed over the cold plate 706 and is typically spaced apart from the cold plate 706 by a gap corresponding to the thickness of the sealing material layer 722. Coolant fluid may be circulated through the coolant chamber volume 710 through the inlet/outlet openings 716, 714 formed through the lateral portion 705B. In each of the embodiments described herein, coolant lines 108 may be attached to the device package 701 by use of connector features formed in the package cover 705, such as threads formed in the sidewalls of respective inlet/outlet openings of the package cover 705 and/or protruding features that surround the respective openings of the package cover 705 and extend upwardly from a surface of the lateral portion 705B.

The sealing material layer 722 forms an impermeable barrier between the integrated cooling assembly 703 and the package cover 705 that prevents coolant from reaching the active side 718 of the device 704 and causing damage thereto. In some embodiments, the sealing material layer 722 comprises a polymer or epoxy material that extends upwardly from the package substrate 702 to encapsulate and/or surround at least a portion of the device 704. In other embodiments, the sealing material layer 722 may be disposed between only the upward facing surface, such as the first side 707, of the cold plate 706 and the portion of the package cover 705 disposed thereover, such as the lateral portion 705B. In some embodiments, the sealing material layer 722 is formed from a molding compound, e.g., a thermoset resin, that when polymerized, forms a hermetic seal between the package cover 705 and the cold plate 706. Here, a coolant fluid may be delivered to the cold plate 706 through openings 722A disposed through the sealing material layer 722. As shown, the openings 722A are respectively in registration and fluid communication with the respective inlet/outlet openings of the package cover 705 thereabove and the inlet/outlet openings 712, 711 in the cold plate 706 therebelow. Typically, coolant lines 108 are attached to the device package 701 by use of connector features formed in the package cover 705, such as threads formed in the sidewalls of the respective inlet/outlet openings of the package cover 705 and/or protruding features that surround the respective inlet/outlet openings of the package cover 705 and extend upwardly from the surface of the lateral portion 705B.

Beneficially, the sealing material layer 722 provides mechanical support that improves system reliability and extends the useful lifetime of the device package 701. For example, the sealing material layer 722 may reduce mechanical stresses that can weaken interfacial bonds and/or electrical connections between electrical components of the device package 701, such as stresses caused by vibrations, mechanical and thermal shocks, and/or fatigue caused by repeated thermal cycles. In some embodiments, the sealing material layer 722 may be a thermally conductive material, such as a polymer or epoxy having one or more thermally conductive additives, such as solder (e.g., In), silver, graphite, and/or other forms of carbon (e.g., graphene or carbon nanoparticles). In some embodiments, the device package 701 includes a support member (not shown) attached to the upward-facing side of the cold plate 706. The support member may be formed of a rigid material, e.g., a metal or ceramic plate, that provides mechanical support to the cold plate 706. The support member may be attached to the cold plate 706 using a direct bonding method or by use of an intervening adhesive layer (not shown).

Here, the cold plate 706 may be attached to the device backside 720 without the use of an intervening adhesive material. In one embodiment, the perimeter of the cold plate 706 may be attached (e.g., directly bonded) to the device backside 720. That is, the base (e.g., lower surfaces) of the cold plate sidewalls 713 may be directly bonded to the device backside 720. The protrusions 724 of the cold plate 706 may be spaced apart from the device backside 720 to define a gap therebetween. The protrusions 724 may be spaced apart from each other to define plural coolant channels therebetween, through which coolant fluid may flow. As discussed above, a single inlet opening of the cold plate may direct fluid to all of the plural coolant channels and a single outlet opening of the cold plate may direct fluid away from all of the plural coolant channels. Lower surfaces of the protrusions 724 facing the device backside 720 may have a substantially flat surface that is substantially parallel with respect to the base surface 709. Here, the protrusions 724 may extend to and/or be bonded to the device backside 720. That is, the outer sidewalls 713 and the protrusions 724 of the cold plate 706 may be directly bonded to the device backside 720 such that the cold plate 706 and the device backside 720 are in direct thermal contact. The backside 720 of the semiconductor device 704 may be bonded to a portion of the second patterned side of the cold plate 706 (e.g., lower surfaces of the sidewalls 713) at the bonded interface. The bonded interface may extend at least along a perimeter of the backside 720. As discussed above, the protrusions may further form a bonded interface with the backside 720. Here, the cold plate 706 is rectangular and the bonded interface extends along at least all four edges of the perimeter of the backside 720.

In some embodiments, the cold plate 706 is attached to the semiconductor device 704 using a direct dielectric bonding process. In other embodiments, the cold plate 306 is attached to the semiconductor device 704 using a hybrid of direct dielectric bonds and direct metal bonds formed therebetween. For example, in some embodiments, one or both of the cold plate 706 and the backside 720 of the semiconductor device 704 comprise a dielectric material layer, e.g., a first dielectric material layer and a second dielectric material layer respectively, and the cold plate 706 is directly bonded to the backside 720 of the semiconductor device 704 through bonds formed between the dielectric material layers.

In some embodiments, the cold plate 706 is attached to the semiconductor device 704 using a hybrid bonding technique, where bonds are formed between the dielectric material layers and between metal features, such as between first metal pads and second metal pads, disposed in the dielectric material layers.

Suitable dielectrics that may be used as the dielectric material layers include silicon oxides, silicon nitrides, silicon oxynitrides, silicon carbon nitrides, metal-oxides, metal-nitrides, silicon carbide, silicon oxycarbides, silicon oxycarbonitride, silicon carbonitride, diamond-like carbon (DLC), or combinations thereof. In some embodiments, one or both of the dielectric material layers are formed of an inorganic dielectric material, e.g., a dielectric material substantially free of organic polymers. Typically, one or both of the dielectric layers are deposited to a thickness greater than the thickness of a native oxide, such as about 1 nanometer (nm) or more, 5 nm or more, 10 nm or more, 50 nm or more, 100 nm or more, or 300 nm or more. In some embodiments, the one or both of the dielectric layers are deposited to a thickness of 300 nm or less, such as 100 nm or less, 80 nm or less, 50 nm or less, 10 nm or less, 5 nm or less, or 1 nm or less.

The cold plate 706 may be formed of any suitable material that has sufficient structural strength to withstand the desired pressures of coolant flowing into the coolant chamber volume 710. For example, the cold plate 706 may be formed of a material selected from a group comprising polymers, metals, ceramics, or composites thereof. In some embodiments, the cold plate 706 may be formed of stainless steel (e.g., from a stainless-steel metal sheet) or a sapphire plate. In some embodiments, the cold plate 706 may be formed from non-crystalline silicon materials, such as a bulk substrate material comprising metal, metal alloys, ceramics, composite materials or other low CTE materials suitable for the bonding using the methods described in the present disclosure. For example, the cold plate 706 may be formed from a bulk material selected from the group comprising copper, aluminum, copper alloys (e.g., copper molybdenum alloys and copper tungsten alloys), iron-cobalt nickel alloys (e.g., Kovar® from Magellan Industrial Trading Co., Inc. of South Norwalk Connecticut USA), iron-cobalt nickel silver alloys, iron-nickel alloys (e.g., Invar® superalloys from Magellan), iron-nickel silicon alloys, aluminum silicon carbides, aluminum-silicon alloys, beryllium, beryllium oxides, beryllium, and beryllium oxide composites, aluminum-graphite fibers, copper-graphite fibers, metal diamond composite materials (e.g., aluminum diamond composites and silver-diamond composites), metal oxides, metal nitrides, and combinations thereof. The non-silicon substrate materials may be prepared for bonding and may or may not include a dielectric material layer deposited on the device-facing side to form a bonding surface.

In some embodiments, the cold plate 706 is formed of a material having a coefficient of thermal expansion (CTE) substantially similar to the CTE of the device substrate of device 704. For example, in some embodiments, the device 704 may be formed on a monocrystalline silicon substrate, and the cold plate 706 may be formed from a monocrystalline silicon or polycrystalline silicon substrate. Forming the cold plate 706 from CTE matched materials (with respect to the bulk substrate material of the device 704) prevents undesired separation of the device 704 and cold plate 706 across repeated thermal cycles.

In some embodiments, the cold plate 706 may be formed of a material having a substantially different CTE from the semiconductor device 704, e.g., a CTE mismatched material. In such embodiments, the cold plate 706 may be attached to the semiconductor device 704 by a compliant adhesive layer (not shown) or a molding material that absorbs the difference in expansion between the cold plate 706 and the semiconductor device 704 across repeated thermal cycles.

As discussed above, the outer sidewalls 713 and the inner sidewalls 714 may define inlet/outlet openings 712, 711 of the cold plate 706. That is, the dimensions and shape of the inlet/outlet openings 712, 711 may be defined by one or more segments of the outer sidewalls 713 being spaced apart from one or more segments of the inner sidewalls 714. It will be understood that the inlet openings 712 and the outlet opening 711 are shown in a section view. The openings 712, 711 may have any cross-sectional shape in the X-Y plane that allows fluid to flow therethrough. For example, the openings 712, 711 may have rectangular or square cross-sections.

The openings of the cold plate 706, such as the inlet opening 712 and outlet opening 711, may be defined by the cold plate sidewalls 713 and the Y-direction protrusion sidewalls 714. That is, a gap may be between a part of the cold plate sidewalls 713 and a part of one or both of the Y-direction protrusion sidewalls 714 and the base surface 709. As illustrated in the sectional side view of FIG. 7, the spacing between a first sidewall of the outer sidewalls 713 left of the inlet opening 712 and a first sidewall of the inner sidewalls 714 right of the inlet opening 712 may define the dimensions and shape of the inlet opening 712. Here, the spacing between the first sidewall of the outer sidewalls 713 and the first sidewall of the inner sidewalls 714 may define an X-direction length and a Y-direction width of the inlet opening 712. Further, the spacing between a second sidewall of the outer sidewalls 713 right of the outlet opening 711 and a second sidewall of the inner sidewalls 714 left of the outlet opening 711 may define the dimensions and shape of the outlet opening 711. Here, the spacing between the second sidewall of the outer sidewalls 713 and the second sidewall of the inner sidewalls 714 may define an X-direction length and a Y-direction width of the outlet opening 711.

Furthermore, the one or both of the outer sidewalls 713 and the inner sidewalls 714 may extend from the first side 707 to the second side 708 to define a respective Z-direction depth of the inlet opening 712 and/or the outlet opening 711. That is, the first sidewall of the outer sidewalls 713 and the first sidewall of the inner sidewalls 714 may extend from the first side 707 to the second side 708, defining a Z-direction depth of the inlet opening 712. The spacings between the outer sidewalls 713 and the inner sidewalls 714 corresponding to inlet/outlet openings 712, 711 may form any cross-sectional shape in the X-Y plane, defining the shapes of the inlet/outlet openings 712, 711 in the X-Y plane.

In some embodiments, the outer sidewalls and/or the inner sidewalls may have a trapezoidal shape in cross section in the X-Z plane. Here, the inlet opening 712 and/or the outlet openings 711 may have an X-direction length that is wider around the backside 708 of the cold plate 706 than proximate to a region of the cold plate 706 around the coolant chamber volume 710, such as a lower surface of the protrusions 724, such as the base surface 709, and/or such as lower segments of the inner sidewalls 714.

Various features of the cold plate 706 may be produced through forming the cold plate 706 using concurrent double-sided anisotropic wet etching. Here, the cold plate sidewalls 713, the base surface 709, and the protrusions 724, and/or segments thereof, such as the X-direction protrusion sidewalls 726 and the Y-direction protrusion sidewalls 714, may be formed through a double-sided wet etch process that concurrently wet etches both sides of a patterned substrate to form the cold plate 306 after the etching. In some beneficial aspects, the cold plate sidewalls 713, the protrusion sidewalls 724, and /r segments thereof, such as the X-direction protrusion sidewalls 726 and the Y-direction protrusion sidewalls 714, may be angled to define a shape of the inlet/outlet openings 712, 711 and the coolant chamber volume 710 that enables smooth coolant flow by widening the flow path towards and through the coolant chamber volume 710.

Portions of the cold plate 706 (e.g., internal surfaces of the cold plate 706) may be polished to a desired surface roughness using a chemical mechanical polishing (CMP) process in preparation for bonding to the device backside 720. As described above, in some embodiments, the cold plate 706 is formed through concurrent double-sided anisotropic etching that leaves a bonding surface (e.g., portions of the etched surfaces) of the cold plate 706 with a desirable surface roughness for direct bonding. That is, the surface roughness of one or more portions of the cold plate 706 may have a range of about 0.1 nm to about 10 nm RMS through forming the cold plate 706 by concurrent double-sided anisotropic etching. Lower surfaces of the cold plate sidewalls 713 facing the device backside 720 may have a surface roughness that enhances the bond strength between the perimeter of the cold plate 706 and the device backside 720. The lower surfaces of the protrusions 724 facing the device backside 720 may have a surface roughness that enhances the bond strength between the protrusions 724 and the device backside 720. In such embodiments, the portions of the cold plate 706 (e.g., lower surfaces of the cold plate sidewalls 713 and/or the lower surface of the protrusions 724) may be left unpolished to retain the unpolished surface roughness. In such embodiments, the protrusions 724 may be bonded to the device backside 720 without polishing prior to the bonding.

Beneficially, the double-sided anisotropic etching concurrently forms the aforementioned features disposed at both sides of the cold plate 706 to reduce manufacturing cost and improve manufacturing efficiency of cold plates, such as the cold plates described herein. In one embodiment, the double-sided anisotropic etching process includes immersing a patterned substrate in a wet etchant bath to form the cold plate 706. In some advantageous aspects, since an anisotropic etch rate may differ based on the crystallographic orientation, the double-sided anisotropic etching provides a high-resolution etch capability with dimensional control in forming the cold plate 706. In some embodiments, the etching process is controlled to where the etch rates of a substrate have a ratio between about 1:10 and about 1:200, such as between about 1:10 and about 1:100, such as between about 1:10 and 1:50, or such as between about 1:25 and 1:75. Some examples of anisotropic wet etchants include aqueous solutions of potassium hydroxide (KOH), ethylene diamine and pyrocatechol (EPD), ammonium hydroxide (HN4OH), hydrazine (N2H4), or tetramethylammonium hydroxide (TMAH). Here, as shown at the inset 730, forming the cold plate 706 through the concurrent double-sided anisotropic etching causes the protrusions 724 to have different width near the base surface 709 of the cold plate 706 than widths at the lower surface of the protrusions 724, e.g., within the coolant chamber volume 710 and/or proximate to the device backside 720. In some advantageous aspects, forming the cold plate 706 through the double-sided anisotropic etching may be adapted for batch processing. That is, a plurality of cold plates having analogous features of the cold plate 706 may be formed by immersing a patterned substrate prepared for patterning the plurality of cold plates. It is noted that the cross-sectional shape due to the double-sided anisotropic etching is described as trapezoidal for illustration and should be considered non-limiting. For example, the anisotropic etching may form pyramidal shapes (or triangular in cross-section).

In embodiments where a patterned substrate is immersed in a wet etchant bath to form the cold plate 706, before the wet etching occurs, a first plurality of hardmasks may be disposed on a first side of the patterned substrate at positions corresponding to the cold plates. Analogously, a second plurality of hardmasks may be disposed on a second side of the patterned substrate. Each plurality of hardmasks may have respective patterns leaving portions of the substrate exposed for etching. The patterned substrate is immersed in the wet etchant, wherein both sides are concurrently etched through exposed portions by the anisotropic etching. Here, the double-sided concurrent etching forms the plurality of cold plates having the aforementioned features of the cold plate 706. Formation of the cold plate 706 through concurrent double-sided anisotropic etching is further described below with respect to FIGS. 8-11.

FIG. 8 shows a schematic sectional side view corresponding to a cold plate 806 having protrusions, such as protrusions 824, in accordance with some embodiments of the present disclosure. The cold plate 806 may comprise one or more features analogous to features of the cold plate 706 as described above with respect to FIG. 7. Here, the cold plate 806 comprises a backside 807, a frontside 808, a base surface 809, outer sidewalls 813, inner sidewalls 814, and protrusions 824. The cold plate 806 is shown along the X-Z plane. One or more sidewalls of the cold plate 806 may include one or more sidewall segments having different textures. In some embodiments, each of the inner sidewalls 814 and the outer sidewalls 813 includes a plurality of segments having different textures. FIG. 8 further illustrates an inset 870. The inset 870 shows a first example sidewall segment 871 having a first surface texture and a second example sidewall segment 872 having a second surface texture, where the first example segment 871 and/or the second example segment 872 may correspond to one or more segments of sidewalls of the cold plate 806 as described below.

The outer sidewalls 813, the inner sidewalls 814, the base surface 809, and the protrusions 824 may collectively define a coolant chamber volume, such as the coolant chamber volume 710, when the cold plate 806 is attached to a semiconductor device, such as the device 704, the base surface 809 being spaced apart from the backside 720 of the device 704. As discussed above, the protrusions 824 may extend to a bonding interface of a semiconductor device. That is, the protrusions 824 may extend to a depth that is level with the bonding interface of the semiconductor device and/or a lower surface of the outer sidewalls 813 such that the protrusions 824 and the outer sidewalls 813 are bonded to the bonding interface of the semiconductor device (e.g., the device backside). Here, the protrusions 824 extend to a depth that is level with the lower surface of the outer sidewalls 813. In some embodiments, the protrusions 824 may extend to a height away from the bonding interface of a device (e.g., the device backside), defining a gap therebetween, and the outer sidewalls 813 are bonded to the bonding interface of the semiconductor device (e.g., the device backside). The outer sidewalls 813 and the inner sidewalls 814 may define openings of the cold plate 806, such as an inlet opening 712 and an outlet opening 711. That is, segments of the outer sidewalls 813 may be spaced apart from segments of the inner sidewalls 814 by an opening therebetween, such as the inlet opening 712 between a first upper outer segment 830 of the outer sidewalls 813 and a corresponding inner segment of the inner sidewalls 814 or such as the outlet opening 711 between a second upper outer segment 834 of the outer sidewalls 813 and a first upper inner segment 856 of the inner sidewalls 814.

As discussed above, one or more sidewalls of the cold plate 806, or at least segments thereof, may be sloped. Here, the outer sidewalls 813 and the inner sidewalls 814 include respective segments sloping away from the backside 807 (or the base surface 809) at an angle greater than or less than 90° as illustrated in FIG. 8. The outer sidewalls 813 include a first upper outer segment 830, a second upper outer segment 834, a first lower outer segment 840, and a second lower outer segment 842. The outer segments 830, 834, 840, 842 may extend along the Y-direction. Here, the first upper outer segment 830 may slope towards the frontside 808 at a first angle 832 that is less than 90°, and the first lower outer segment 840 may slope towards the backside 807 at an angle less than 90° (or slopes away from the frontside 808 at an angle greater than 90°). The outer sidewalls 813 further include a first vertical outer segment 836 extending along the Z-direction between the first upper outer segment 830 and the first lower outer segment 840 and a second vertical outer segment 838 extending along the Z-direction between the second upper outer segment 834 and the second lower outer segment 842.

In some embodiments, the outer sidewalls 813 and/or the inner sidewalls 814 comprise a plurality of segments, where the plurality of segments may slope away from a first side at a plurality of angles. That is, the inner sidewalls 814 may include the Y-direction protrusion sidewalls 852, the first upper inner segment 856, and the second upper inner segment 860 that slope away from the backside 807 at respective angles 854, 858, 862. In some embodiments, the plurality of segments may slope away from a first side at angles ranging from about 30° to about 150°, such as about 145° or less, about 110° or less, about 80° or less, about 60° or less, about 45° or less, or about 35° or less. Although not illustrated in FIG. 4, it is contemplated that the vertical outer segments 836, 838 may include sidewall segments that slope away from the backside 807 at respective angles greater than or less than 90°.

As illustrated in FIG. 8, the inner sidewalls 814 include Y-direction protrusion sidewalls 852 of the protrusions 824 that slope away from the base surface 809 at a second angle 854 greater than 90°. The inner sidewalls 814 further include a first upper inner segment 856 and a second upper inner segment 858 extending along the Y-direction proximate to the outlet opening 711. Here, the first upper inner segment 856 may slope towards the base surface 809 or the frontside 808 at a third angle 858 that is less than 90° (or slopes away from the backside 807 at an angle greater than 90°), and the second upper inner segment 860 slopes towards the backside 807 at a fourth angle 862 that is less than 90°.

As discussed above, the cold plate 806 may be formed through a double-sided anisotropic etch process. That is, the double-sided anisotropic etch process may form the protrusions 824, the outer sidewalls 813, the inner sidewalls 814, and/or sidewall segments thereof. In one embodiment, sidewalls of the protrusions 824 may slope away from a first side at an angle greater than 90°. Here, the Y-direction protrusion sidewalls 852 may slope away from the base surface 809 (or the backside 807) at the angle 854 greater than 90°. In one embodiment, one or more segments of a plurality of segments of at least one of the inner sidewalls 814 and the outer sidewalls 813 slope towards a second side at an angle less than 90°. Here, the first upper outer segment 830 may slope towards the frontside 808 at the first angle 832 that is less than 90°, and the first upper inner segment 856 may slope towards the frontside 808 at the third angle 858 that is less than 90°. In one embodiment, one or more segments of at least one of the inner sidewalls 814 and the outer sidewalls 813 slope towards a first side at an angle less than 90°. Here, the first lower outer segment 840 may slope towards the backside 807 at an angle less than 90°, and the second upper inner segment 860 slopes towards the backside 807 at the fourth angle 862 that is less than 90°. In one embodiment, one or more first segments of the inner sidewalls 814 may slope away from a second side at an angle less than 90°, and one or more second segments of the inner sidewalls 814 may slope away from a first side at an angle less than 90°. Here, the first upper inner segment 856 may slope towards the frontside 808 at the third angle 858 that is less than 90°, and the second upper inner segment 860 slopes towards the backside 807 at the fourth angle 862 that is less than 90°.

The protrusions 824 may comprise distal segments and a central segment extending between the distal segments. As illustrated in FIG. 8, a protrusion sidewall of the inner sidewalls 814 may include a first distal segment, a second distal segment, and a central segment extending therebetween. Here, the first distal segment, the second distal segment, and the central segment extend along the X-direction. The first distal segment and the second distal segment may be sloped, such as the Y-direction protrusion sidewalls 852 sloping away from the base surface 809 at the second angle 854 greater than 90°, and the central segment may be substantially parallel to the base surface 809. The first distal segment and the second distal segment may have respective X-direction lengths that are less than an X-direction length of the central segment.

Sidewalls of the cold plate 806 may include one or more sidewall segments having different textures, due to the double-sided anisotropic etch process. In one embodiment, each of the inner sidewalls 814 and the outer sidewalls 813 includes a plurality of segments having a plurality of different textures, respectively. That is, the first upper outer segment 830 may have a first surface texture, such as the first example sidewall segment 871, and the second upper inner segment 860 may have a second surface texture that is different than the first surface texture, such as the second example sidewall segment 872. In some embodiments, distal segments of the outer sidewalls 813 may have a different surface texture than one or more sidewall segments extending between the distal segments. That is, the first upper outer segment 830 and the first lower outer segment 840 may have a first surface texture, such as the first example sidewall segment 871, and the first vertical outer segment 836 may have a second surface texture, such as the second example surface texture 872. In some embodiments, the first surface texture may have a surface roughness that is less than the second surface texture. That is, the first upper outer segment 830 and the first lower outer segment 840 may have a surface roughness that is less than the first vertical outer segment 836. In one embodiment, the first upper inner segment 856, the first and second upper outer segments 830, 834, and the first and second lower outer segments 840, 842 may have a surface roughness that is less than the second upper inner segment 860 and the second vertical outer segment 838.

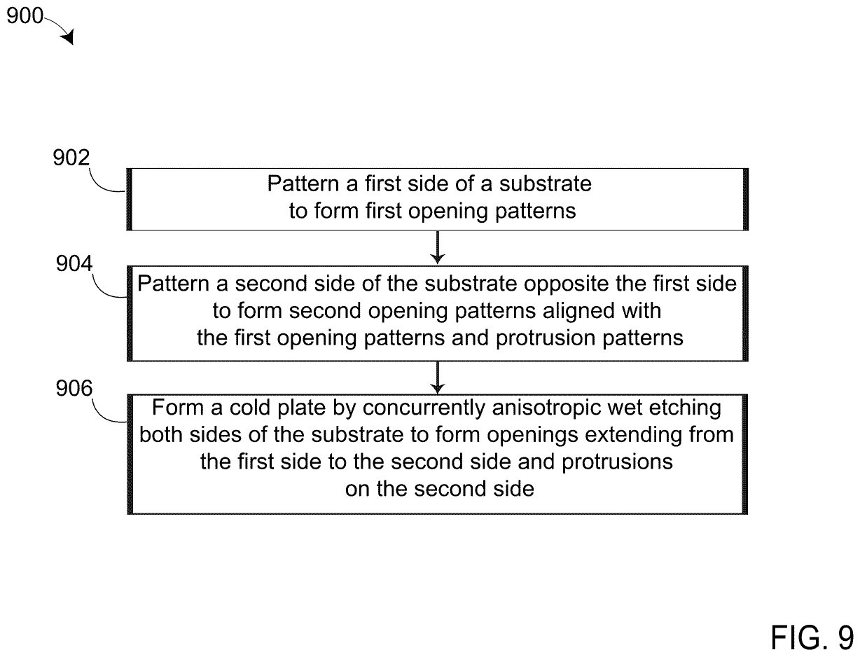

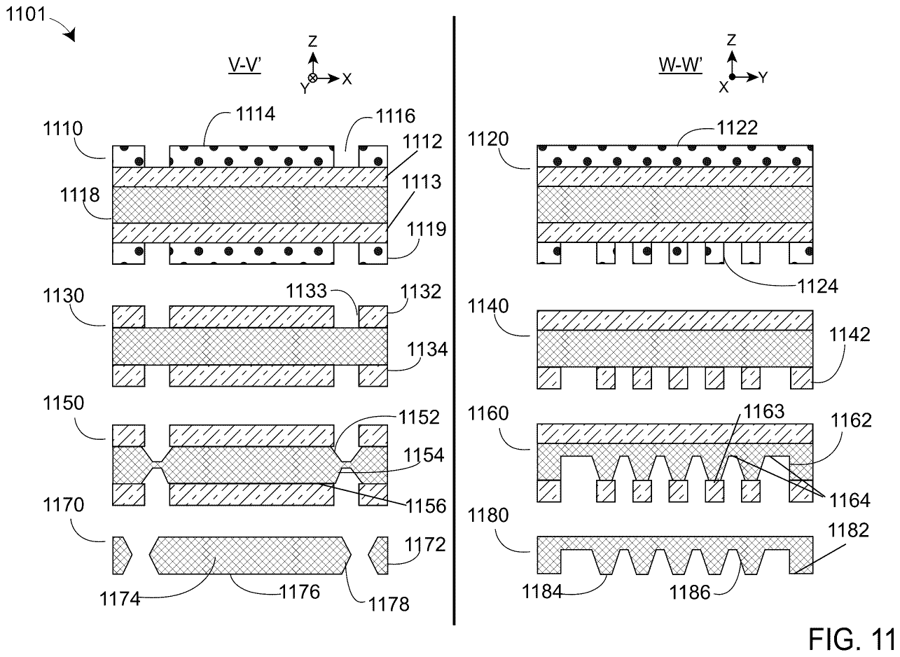

FIGS. 9-11 show an illustrative process for forming a cold plate through double-sided anisotropic etching and some example structures that may be part of the process. FIG. 9 is a flowchart illustrating an example process 900 for forming a cold plate through double-sided anisotropic etching, in accordance with some embodiments of the present disclosure. FIG. 10 shows schematic backside views 1001, 1002 and frontside views 1003, 1004 of example structures 1000 during formation of a cold plate through double-sided anisotropic etching, in accordance with some embodiments of the present disclosure. The views 1001, 1003 show respective backside and frontside views before a double-sided wet etch. The views 1002, 1004 show respective backside and frontside views after the double-sided wet etch. Sectional side views taken along the lines 1060, 1062 (denoted V-V′, W-W′ respectively) are described with respect to FIG. 11. FIG. 11 shows some example intermediate structures 1101 that may arise during formation of a cold plate through double-sided anisotropic etching, in accordance with some embodiments of the present disclosure. Schematic sectional views of the structures 1101 are depicted, taken along the lines V-V′ in the X-Z plane and W-W′ in the Y-Z plane. Here, the process 900 may be employed in forming a cold plate having features as illustrated at views 1002, 1004 and/or blocks 1170, 1180 with respect to FIGS. 10-11. The process 900 is described in the following paragraphs with reference to the example structures 1000, 1101 for illustrative purposes and should not be construed as limited to such structures or parts thereof.

At block 902, a first side of a substrate is patterned to form first opening patterns, such as illustrated at backside view 1001. The first opening patterns may alternatively be referred to as patterns of first openings. The substrate may comprise crystalline silicon. In one embodiment referring to FIG. 10, patterning the first side of the substrate comprises depositing a first hardmask 1032 with the first opening patterns 1030 on the first side of a substrate 1034. The first hardmask 1032 may comprise amorphous dielectric, such as thermal oxide. That is, a substrate may be obtained having 1 to 2 μm of thermal oxide disposed on both sides of the substrate. A first side of the substrate may be patterned with a first resist layer. The thermal oxide may be patterned through the first resist layer using dry or wet etching. The first resist layer may be removed after patterning the first side. Referring to FIG. 11, thermal oxide layers 1112, 1113 are disposed on respective sides of a substrate 1118, and respective resist layers 1114, 1119 are disposed on the respective thermal oxide layers 1112, 1113. The thermal oxide layer 1112 may be etched by photolithography through the resist layer 1114 to transfer the resist patterns 1116, 1122 from the resist layer 1114 to the thermal oxide layer 1112 as the first opening patterns. The resist layer 1114 may be removed after forming the first opening patterns.

At block 904, a second side of the substrate is patterned to form second opening patterns and protrusion patterns. The second opening patterns may alternatively be referred to as patterns of second openings. The second side may be opposite the first side. The second opening patterns may be aligned with the first opening patterns. In one embodiment referring to FIG. 10, patterning the second side comprises depositing a second hardmask 1036 with the second opening patterns and the protrusion patterns, such as second opening patterns 1040 having cavity dividers as the protrusion patterns 1038, on the second side of a substrate 1034. The second hardmask may comprise amorphous dielectric, such as thermal oxide. That is, the second side of the substrate may be patterned through a second resist layer using dry or wet etching. The substrate may be cleaned by cleaning the substrate after removing each resist layer from a respective side. Both sides of the substrate may be cleaned concurrently after the patterning and removing the resist layers. Referring to FIG. 11, a thermal oxide layer 1113 may be etched by photolithography through a second resist layer 1119 to transfer the resist patterns, such as protrusion resist pattern 1124, to the thermal oxide layer 1113 as the second opening patterns and the protrusion patterns. The resist layer 1119 may be removed after forming the second opening patterns and the protrusion patterns.

Referring to FIG. 10, the views 1001-1004 show the backside and the frontside of an example structure 1000 before the double-sided anisotropic wet etching and after the double-sided anisotropic wet etching. Here, the patterned substrate 1034 comprises first and second hardmasks 1032, 1036 disposed on respective sides of the substrate 1034. The backside view 1001 before the double-sided anisotropic wet etching shows a first hardmask 1032 disposed on a backside of the substrate 1034. The first hardmask 1032 has first opening patterns 1030 with openings that expose portions of the substrate 1034 for forming inlet/outlet openings of a cold plate. The first hardmask 1032 may comprise an amorphous dielectric, such as an oxide (e.g., a thermal oxide). Here, the first hardmask 1032 may be formed through thermal oxidation. The first opening patterns 1030 of the first hardmask 1032 may be used for forming inlet/outlet openings of a cold plate, such as inlet/outlet openings 1012, 1011, by etching the exposed substrate portions through the first opening patterns 1030. The frontside view 1003 before the double-sided anisotropic wet etching includes a second hardmask 1036 disposed on a frontside of the substrate 1034. The second hardmask 1036 has second opening patterns 1040 and protrusion patterns 1038 with openings between cavity dividers of the protrusion patterns 1038. Each cavity divider of the protrusion patterns 1038 may have a rectangular shape with X-direction length 1042 and Y-direction width 1044. The second hardmask 1036 may comprise an amorphous dielectric, such as an oxide (e.g., a thermal oxide). Here, the second hardmask 1036 may be formed through thermal oxidation. In one embodiment, the hardmasks 1032, 1036 are concurrently formed through thermally oxidizing both sides of the substrate 1034. In one embodiment, the hardmasks 1032, 1036 may be thermal oxide layers having a thickness of about 0.1 to about 6 μm, such as about 5 μm or less, about 3 μm or less, about 1 μm or less, or about 0.5 μm or less. It is appreciated that the opening patterns 1030, 1040 depicted at FIG. 10 are intended to be illustrative and non-limiting. In embodiments where a plurality of cold plates is formed through the double-sided anisotropic wet etching, the opening patterns 1030, 1036 may be repeated at patterning sites corresponding to each cold plate of the plurality of cold plates.

Referring back to FIG. 11, at blocks 1110 and 1120, the substrate 1118 has patterning layers disposed on respective sides. That is, the first resist layer 1114 is disposed on a first thermal oxide layer 1112 (e.g., a hardmask layer). The thermal oxide layer 1112 is disposed on a side of the substrate 1118 (e.g., the backside). The resist layer 1114 has first opening patterns, such as an opening pattern 1116 as viewed from the line V-V′ and an opening pattern 1122 as viewed from the line W-W′. A second resist layer 1119 is disposed on a second thermal oxide layer 1113, where the second thermal oxide layer is disposed on an opposite side of the substrate 1118 (e.g., the frontside). The resist layer 1119 has second opening patterns, such as the protrusion resist pattern 1124 as viewed from the line W-W′. In one embodiment, the resist layers 1114, 1119 may be photoresist layers, and the opening patterns, including patterns 1116, 1122, 1124, may be transferred to the corresponding thermal oxide layers 1112, 1113 through photolithography.

At blocks 1130, 1140, the thermal oxide layers 1112, 1113 have been patterned by transferring the respective opening patterns from the resist layers 1114, 1119 to form first and second patterned thermal oxide layers 1132, 1134. The first patterned thermal oxide layer 1132 has first opening patterns 1133, and the second patterned thermal oxide layer 1134 has second opening patterns and protrusion patterns 1142. The resist layers 1114, 1119 are removed from the patterned thermal oxide layers 1132, 1134, respectively. The substrate 1118 may be cleaned before proceeding with the double-sided anisotropic etching. In one embodiment, the top and bottom surfaces of the substrate 1118 may be patterned through the first and second photoresist layers to transfer the patterns 1116, 1122, 1124 to the thermal oxide layers 1112, forming thermal oxide mask layers (e.g., thermal oxide hard masks) having respective patterns, such as the first opening patterns 1133 and the protrusion patterns 1142. The thermal oxide mask layers may be selective to anisotropic etching compared to the substrate 1118. In some embodiments, the thermal oxide mask layers have a thickness of about 100 nm or less, such as about 50 nm or less, or about 30 nm or less. It is noted and appreciated that the patterning may use any suitable combination of lithography and material etching patterning methods without departing from the teachings of the present disclosure.

At block 906, a cold plate is formed by concurrently anisotropic wet etching both sides of the substrate to form openings extending from the first side to the second side and protrusions on the second side. The substrate may be etched at substrate portions exposed by the first and second opening patterns and the protrusion patterns through a concurrent double-sided anisotropic wet etch. That is, both sides of the substrate may be concurrently etched using an anisotropic wet etchant, such as a TMAH or KOH solution. The substrate may be etched to form a cold plate using the wet etchant at an elevated temperature. In one embodiment, the wet etchant may have a temperature in a range from about 80° C. to about 100° C., such as about 90-95° C. or less (e.g., about 93° C. or less). After etching through the substrate from both sides to form a cold plate, the thermal oxide may be removed using a hydrofluoric acid (HF) solution or another suitable chemical. In one embodiment referring to FIG. 10, forming the cold plate by concurrently anisotropic wet etching both sides of the substrate comprises anisotropic wet etching the backside of the substrate 1034 through substrate portions exposed by the first opening patterns, such as openings 1030, and anisotropic wet etching the frontside of the substrate 1034 through substrate portions exposed by the second opening patterns and the protrusion patterns, such as the second opening patterns 1040 and the protrusion patterns 1038.

Referring to FIG. 11 at blocks 1150 and 1160, forming the cold plate by concurrently anisotropic wet etching both sides of the substrate may form first Y-direction sidewalls 1152 disposed on a first side of the cold plate that slope away from the first side, second Y-direction sidewalls 1154 disposed on a second side of the cold plate that slope away from the second side, and cold plate sidewalls 1162 defining a perimeter of the cold plate. The first Y-direction sidewalls 1152 and the second Y-direction sidewalls 1154 may define a site for forming an opening, such as an inlet opening or an outlet opening. Further, the double-sided anisotropic wet etching may form a base surface 1164, protrusions 1156 extending downwardly from the base surface 1164. Here, each of the protrusions 1156 may have distal segments and a central segment extending in the Y-direction, the central segment having a lower surface 1163. Here, the protrusions 1156 may extend to a depth that is level with a bonding interface of a device (e.g., the device backside). That is, the lower surface 1163 may be bonded to the bonding interface of a device (e.g., the device backside). In some embodiments, the lower surface 1163 of the protrusions 1156 may extend to a depth that is away from a bonding interface of a device (e.g., the device backside), defining a gap therebetween. The hardmasks may be removed after forming the cold plate.

At blocks 1170, 1180, the double-sided anisotropic wet etch proceeds through the portions of the substrate 1118 exposed by the first and second patterned thermal oxide layers 1132, 1134. The first and second patterned thermal oxide layers 1132, 1134 are removed after the etching. A cold plate 1172 is formed having base surface 1174, protrusions 1176 extending along the X-direction, Y-direction protrusion sidewalls 1178, and X-direction protrusion sidewalls 1186. Each of the protrusions 1176 may have a lower surface 1184. The cold plate 1172 further comprises cold plate sidewalls 1182 (e.g., outer sidewalls) that define an outer perimeter of a coolant chamber volume when attached to a device. Beneficially, both sides of the cold plate 1172 may be concurrently formed through double-sided anisotropic wet etching and produce protrusions, such as protrusions 1176, that enhance the cooling efficiency of the cold plate 1172. It is noted that the example structures 1000, 1101 are intended to be illustrative. It is appreciated that a cold plate may be formed through the double-sided anisotropic wet etching in various ways without departing from the teachings of the present disclosure. For example, one or more steps of the depicted process may be added, substituted, removed, etc., to form the cold plates 706, 806 having desirable protruding features.

As discussed above, the substrate 1034 with the hardmasks 1032, 1036 may be immersed in a wet etchant bath to concurrently etch both sides, where the hardmasks 1032, 1036 are resistant to the wet etchant. The wet etchant selectively etches the substrate 1034 through the first opening patterns 1030 and the second opening patterns 1036. The hardmasks 1032, 1036 are removed after the double-sided etching.

The backside view 1002 and the frontside view 1004 show an example structure 1000 after the double-sided etching. The views 1002, 1004 respectively show the backside 1007 and frontside 1008 of a cold plate including inlet/outlet openings 1012, 1011 disposed therethrough, outer sidewalls 1013, protrusions 1024, and a base surface 1009. The protrusions 1024 may correspond to protrusions 724 or protrusions 824 as described with respect to FIGS. 7-8. Here, the protrusion patterns 1038 of the second hardmask 1036 may be selected to form the protrusions 1024 having inner sidewalls 1014. Here, each protrusion of the protrusions 1024 traverses the base surface 1009, extending laterally along the X-direction between the inlet/outlet openings 1012, 1011. Each protrusion may have X-direction protrusion sidewalls 1026, a rectangular central segment 1046 extending along the X-direction, triangular distal segments 1048 disposed at first and second lateral end portions 1050 of the protrusion along the X-direction. The rectangular central segment 1046, the triangular distal segments 1048, and the first and second lateral end portions 1050 of each protrusion may form a convex hexagonal shaped cross section, such as an elongated diamond shape in the X-Y plane as illustrated in FIG. 10. Here, the frontside 1008 of the cold plate comprises cold plate sidewalls 1013 defining a perimeter of the cold plate.

The elongated diamond shape (e.g., convex hexagonal cross-section) of the protrusions 1024 may modify coolant channel flow through a coolant chamber volume when the cold plate is attached to a device (e.g., the coolant chamber volume 710). Beneficially, the modified coolant channel flow enhances heat transfer from an attached device. Here, coolant fluid may enter a coolant chamber volume through the inlet opening 1012. The coolant fluid flows across the inner surfaces of the cold plate between the cold plate sidewalls 1013 and the protrusions 1024. The coolant fluid flows across the inner surfaces of the cold plate such that heat generated by an attached semiconductor device is directly absorbed via the device backside and/or via the cold plate after dissipation. Here, the distal segments 1048 and the lateral end portions 1050 may disrupt the laminar fluid flow of the coolant fluid, which may increase the heat transfer. The coolant fluid exits the coolant chamber volume through the outlet opening 1011.

As discussed with respect to FIG. 7, in some embodiments, the angle of the distal segments of the X-direction protrusion sidewalls towards each other, here in the X-Y plane, may form distal segments having other cross-sectional shapes than triangular. That is, the central segments and the distal segments may form protrusions with a cross-sectional shape in the X-Y plane other than a hexagonal shaped cross-section. The angle of the distal segments of the X-direction protrusion sidewalls towards each other may form rectangular distal segments, trapezoidal distal segments, rounded distal segments, etc. That is, the central segments and the distal segments may form protrusions with respective cross-sectional shapes in the X-Y plane, such as rectangular or nearly rectangular, octagonal, or other polygonal, oval, elliptical, etc. Protrusions with a rectangular or nearly rectangular cross-sectional shape may be formed where the angle of the distal segments of the X-direction protrusion sidewalls toward each other are in a range of about 0° to about 15° away from X-direction protrusion sidewalls 1026.

In some embodiments, a planar protrusion sidewall may extend between the angled distal segments of the X-direction protrusion sidewalls, such as planar Y-direction protrusion sidewalls of the distal segments. Here, the distal segments of the X-direction protrusion sidewalls form trapezoidal distal segments, and the central segments and the distal segments form protrusions with octagonal or other polygonal cross-sectional shapes in the X-Y plane. In some embodiments, a curved protrusion sidewall, such as an arc, may extend between the angled distal segments of the X-direction protrusion sidewalls. Here, the distal segments of the X-direction protrusion sidewalls form rounded distal segments, and the central segments and the distal segments form protrusions with oval or elliptical cross-sectional shapes in the X-Y plane. The Y-direction protrusion sidewalls of the distal segments may be sloped, such as the Y-direction protrusion sidewalls 852 sloping away from the backside 807 at the angle 854.

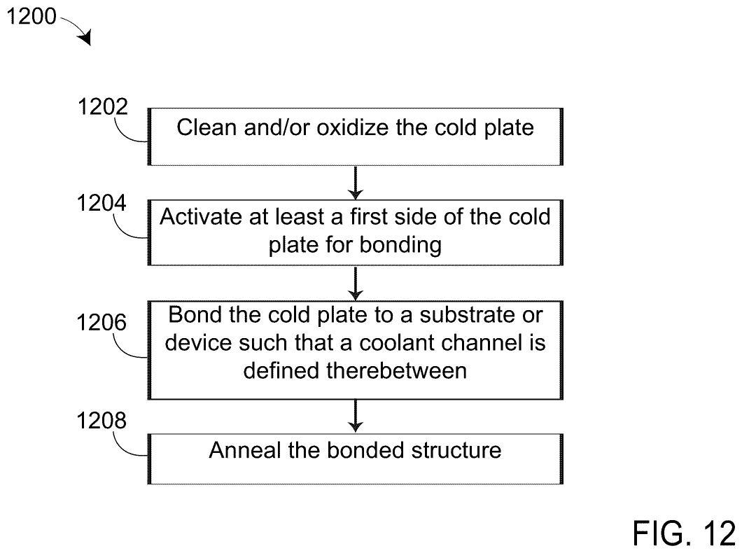

FIG. 12 is a flowchart illustrating an example process 1200 for assembling an integrated cooling assembly having a cold plate with protrusions, in accordance with some embodiments of the present disclosure. The process 1200 may be employed in assembling the integrated cooling assembly 703. One or more components of the integrated cooling assembly 703 may be formed corresponding to one or more blocks of the process 1200.

At block 1202, a cold plate is cleaned and/or oxidized. That is, a cold plate formed through the process 900 may be cleaned to remove the hardmasks. In some embodiments, a portion of the hardmasks comprising thermal oxide remains on the cold plate. Additionally, or alternatively, the cold plate is oxidized to form an oxide layer. In some beneficial aspects, the oxide layer may enhance the structural integrity of the cold plate.

In one embodiment, the process 1200 may include forming dielectric layers on the cold plate and the device, and the two surfaces are directly bonded by forming dielectric bonds between a first dielectric material layer of the cold plate and a second dielectric material layer of the device backside.

Preparing a side of the cold plate for bonding with the device backside may include smoothing the respective surfaces (wafer surfaces or die surfaces) to a desired surface roughness, such as between 0.1 to 3.0 nm RMS, activating the surfaces to weaken or open chemical bonds in the dielectric material, and terminating the surfaces with a desired species. Smoothing the surfaces may include polishing the surfaces using a chemical mechanical polishing (CMP) process. Activating and terminating the surfaces with a desired species may include exposing the surfaces to radical species formed in a plasma.

At block 1204, at least a portion of a side of the cold plate is activated for bonding. That is, the sidewalls around a perimeter of the cold plate and a plurality of protrusions extending to a device may be activated through plasma activation. In some embodiments, a bonding interface of a substrate or a device may also be activated for bonding. That is, a backside of a device may be activated through plasma activation.

In some embodiments, the plasma is formed using a nitrogen-containing gas, e.g., N₂, and the terminating species includes nitrogen and hydrogen. In some embodiments, the surfaces may be activated using a wet cleaning process, e.g., by exposing the surfaces to an aqueous ammonia solution. In some embodiments, the dielectric bonds may be formed using a dielectric material layer deposited on only one of the surfaces but not on both. In those embodiments, the direct dielectric bonds may be formed by contacting the deposited dielectric material layer of one surface directly with a bulk material surface of the other surface.

At block 1206, the cold plate is bonded to a device such that a coolant channel, or a part thereof, is defined therebetween (e.g., a coolant chamber volume). That is, a first portion of a side of the cold plate may be directly bonded to a side of a second substrate comprising a semiconductor device, and a second portion of the side of the cold plate may be spaced apart from the side of the second substrate. Here, the bonded first and second substrates may form an integrated cooling assembly.

Directly forming direct dielectric bonds between the surfaces includes bringing the prepared and aligned surfaces into direct contact at a temperature less than 150° C., such as less than 100° C., for example, less than 30° C., or about room temperature, e.g., between 20° C. and 30° C. Without intending to be bound by theory, it is believed that the hydrogen terminating species diffuse from the interfacial bonding surfaces, and chemical bonds are formed between the remaining nitrogen species during the direct bonding process.

At block 1208, the bonded structure comprising the cold plate and the device may be annealed. In one embodiment, the cold plate and the device may be heated to and maintained at a temperature of greater than about 30° C. and less than about 450° C., such as greater than about 50° C. and less than about 250° C., or about 150° C. for a duration of about 5 minutes or more, such as about 15 minutes. Typically, the bonds will strengthen over time even without the application of heat.

After the dielectric bonds are formed, the surfaces may be heated to a temperature of 150° C. or more and maintained at the elevated temperature for a duration of about 1 hour or more, such as between 8 and 24 hours, to form direct metallurgical bonds between the metal features. Suitable direct dielectric and hybrid bonding technologies that may be used to perform aspects of the methods described herein include ZiBond® and DBI®, each of which are commercially available from Adeia Holding Corp., San Jose, CA, USA.

The bonded structure may be an integrated cooling assembly that becomes part of a device package having integrated liquid cooling. In embodiments where a first substrate comprising a plurality of cold plates is formed through the double-sided anisotropic etching, the first substrate may be aligned and bonded to a second substrate comprising corresponding devices, wherein the bonded substrates are singulated to form a plurality of integrated cooling assemblies, each comprising a cold plate bonded to a corresponding device.

In one embodiment, the cold plate may be thermally oxidized by leaving some thermal oxide or forming another thermal oxide layer. The thermal oxide may provide structural support for the cold plate.

It is contemplated that the processes above are not limited to crystalline silicon as sloped surfaces can be formed using other methods known to those skilled in the art. Thus, in some embodiments, the cold plates may be formed of a bulk material having a substantially similar coefficient of linear thermal expansion (CTE) to the bulk material of the device, where the CTE is a fractional change in length of the material (in the X-Y plane) per degree of temperature change. In some embodiments, the CTEs of the first and second substrates are matched so that the CTE of the second substrate is within about +/−20% or less of the CTE of the first substrate, such as within +/−15% or less, within +/−10% or less, or within about +/−5% or less when measured across a desired temperature range. In some embodiments, the CTEs are matched across a temperature range from about −60° C. to about 100° C. or from about 60° C. to about 175° C. In one example embodiment, the matched CTE materials each include silicon.

The methods and device packages described herein advantageously provides for integrated cooling assemblies with increased convective heat transfer from a semiconductor device to a coolant fluid, which facilitates an increase in power density of advanced device packages. One or more embodiments herein provide for fabricating liquid cooling channel modules that may be attached, for example, to a microelectronic chip as part of an integrated cooling system. Advantageously, the fabrication process involves double-sided anisotropic etching (e.g., using a wet etchant) that produces a cold plate as an inexpensive add-on module having features that enhance liquid cooling system performance and efficiency. Furthermore, channel features for both sides of the cold plate as an add-on module may be formed concurrently and in batches using double-sided anisotropic wet etching.

The embodiments discussed above are intended to be illustrative and not limiting. One skilled in the art would appreciate that individual aspects of the cooling assemblies, device packages, and methods discussed herein may be omitted, modified, combined, and/or rearranged without departing from the scope of the disclosure.

1. A method of manufacturing a cold plate, the method comprising:
patterning a first side of a substrate to form first opening patterns;
patterning a second side of the substrate opposite the first side to form:
second opening patterns aligned with the first opening patterns; and
protrusion patterns;
forming a cold plate by concurrently anisotropic wet etching both sides of the substrate to form:
openings extending from the first side to the second side; and
protrusions on the second side.

2. The method of claim 1, wherein the patterns comprise a thermal oxide layer.

3. The method of claim 1, wherein:
patterning the first side of the substrate comprises depositing a first hardmask with the first opening patterns on the first side of the substrate; and
patterning the second side of the substrate comprises depositing a second hardmask with the second opening patterns and the protrusion patterns on the second side of the substrate.

4. The method of claim 3, wherein:
the substrate comprises crystalline silicon; and
the first and second hardmasks comprise amorphous dielectric.

5. The method of claim 4, wherein the amorphous dielectric is a thermal oxide.

6. The method of claim 3, wherein forming the cold plate by concurrently anisotropic wet etching both sides of the substrate comprises:
anisotropic wet etching the first side through first substrate portions exposed by the first opening patterns;
anisotropic wet etching the second side through second substrate portions exposed by the second opening patterns and the protrusion patterns; and
removing the first and second hardmasks.

7. The method of claim 1, wherein a first side of the cold plate comprises a base surface.

8. The method of claim 7, wherein the substrate is a first substrate, the method further comprising:
attaching the first side of the cold plate to a second substrate comprising a semiconductor device, the base surface being spaced apart from the semiconductor device to define a coolant channel therebetween, wherein the attached cold plate and second substrate form an integrated cooling assembly.

9. The method of claim 8, wherein attaching the first side of the cold plate to the second substrate comprises direct dielectric bonding.

10. The method of claim 8, wherein attaching the first side of the cold plate to the second substrate comprises direct hybrid bonding.

11. The method of claim 1, further comprising:
activating a first side of the cold plate for bonding; and
directly bonding the first side of the cold plate to a second substrate comprising a semiconductor device, wherein the bonded first and second substrates form an integrated cooling assembly.

12. The method of claim 11, wherein the first side of the cold plate is not polished prior to bonding.

13. The method of claim 11, wherein:
the first side of the cold plate comprises a base surface; and
the base surface is spaced apart from the semiconductor device to define a coolant channel therebetween.

14. The method of claim 13, further comprising:
sealingly attaching a package cover to a second side of the cold plate by use of a material layer disposed therebetween, wherein the package cover comprises an inlet opening and an outlet opening; and
forming openings in the material layer to fluidly connect the inlet opening and outlet opening to the coolant channel.

15. The method of claim 11, wherein directly bonding the first side of the cold plate to the second substrate comprises direct dielectric bonding.

16. The method of claim 11, wherein directly bonding the first side of the cold plate to the second substrate comprises direct hybrid bonding.

17. The method of claim 1, wherein concurrently anisotropic wet etching both sides of the substrate comprises exposing the substrate to an aqueous solution comprising one or more of: potassium hydroxide, ethylene diamine and pyrocatechol, ammonium hydroxide, hydrazine, or tetramethylammonium hydroxide.

18. The method of claim 1, wherein concurrently anisotropic wet etching both sides of the substrate is performed at a temperature in a range from 80 degrees Celsius to 100 degrees Celsius.
